(19) United States
(12) Patent Application Publication
(10) Pub. No.: US 2026/0254447 A1
(43) Pub. Date: Aug. 27, 2026

(54) METHODS AND APPARATUS TO INTERPOLATE BETWEEN VOLTAGES IN A DELAY DOMAIN

(71) Applicant: Texas Instruments Incorporated, Dallas, TX (US)

(72) Inventors: Neeraj Shrivastava, Bangalore (IN); Girish O, Thrissur (IN); Rishi Soundararajan, Bangalore (IN)

(21) Appl. No.: 19/064,074

(22) Filed: Feb. 26, 2025

(51) Int. Cl. H03K 5/24; H03K 5/00; H03M 1/12; H03M 1/66

(52) U.S. Cl. CPC H03K 5/24; H03M 1/12; H03M 1/66; H03K 2005/00019

(57) ABSTRACT

An example apparatus includes: first voltage comparator having an input and an output; second voltage comparator having an input and an output, the input of the second voltage comparator coupled to the input of the first voltage comparator; and delay comparator having a first input and a second input, the first input of the delay comparator coupled to the output of the first voltage comparator, the second input of the delay comparator coupled to the output of the second voltage comparator.

### REFERENCE TO RELATED APPLICATION

This patent application herein incorporates by reference in its entirety “Delay Based Comparator” U.S. patent application Ser. No. 17/181,073 and “Multi-Bit Voltage-to-Delay Conversion in Data Converter Circuitry” U.S. patent application Ser. No. 18/966,610, which are assigned to the assignee of the instant application.

### TECHNICAL FIELD

This description relates generally to voltage comparisons and, more particularly, to methods and apparatus to interpolate between voltages in a delay domain.

### BACKGROUND

An analog-to-digital converter (ADC) generates a digital output signal responsive to an analog input signal. Digital output signal of the ADC allow digital systems to perform digital signal processing operations using digital representations of the analog input signal. Some ADC circuitry implements a pipeline design to produce different portions of a digital value that represents the analog input signal. Pipeline designs include a plurality of sequential stages. The sequential stages respectively include a sub-ADC that produces a relatively low-resolution digital representation of the analog input signal. The sub-ADC, also referred to as a flash ADC (FADC), includes a series of comparators to compare the analog input to a series of reference voltages. The comparators produce sign bits representing the result of the comparison. Alignment and correction circuitry combines the sign bits from the FADCs of the pipeline stages to produce a relatively high-resolution digital representation of the analog input signal.

### SUMMARY

For methods and apparatus to interpolate between voltages in a delay domain, an example apparatus includes first voltage comparator having an input and an output; second voltage comparator having an input and an output, the input of the second voltage comparator coupled to the input of the first voltage comparator; and delay comparator having a first input and a second input, the first input of the delay comparator coupled to the output of the first voltage comparator, the second input of the delay comparator coupled to the output of the second voltage comparator. Other examples are described.

For methods and apparatus to interpolate between voltages in a delay domain, an example apparatus includes reference generation circuitry having a first output and a second output; a voltage comparator stage having a first input, a second input, a first output, and a second output, the first input of the voltage comparator stage coupled to the first output of the reference generation circuitry, the second input of the voltage comparator stage coupled to the second output of the reference generation circuitry; and a delay comparator stage having a first input and a second input, the first input of the delay comparator stage coupled to the first output of the voltage comparator stage, the second input of the delay comparator stage coupled to the second output of the voltage comparator stage. Other examples are described.

For methods and apparatus to interpolate between voltages in a delay domain, an example analog-to-digital converter (ADC) circuitry including: a voltage comparator stage having an input, a sign output, a first delay output, and a second delay output; and a delay comparator stage having a first input, a second input, and a sign output, the first input of the delay comparator stage coupled to the first delay output of the voltage comparator stage, the second input of the delay comparator stage coupled to the second delay output of the voltage comparator stage; a digital-to-analog converter (DAC) having an input and an output, the input of the DAC coupled to the sign output of the voltage comparator stage and the sign output of the delay comparator stage; and amplifier having an input coupled to the input of the voltage comparator stage and the output of the DAC. Other examples are described.

### BRIEF DESCRIPTION OF THE DRAWINGS

FIG. 1 is a block diagram of an example pipeline ADC including a flash ADC (FADC).

FIG. 2 is a block diagram of the example FADC of FIG. 1 including example reference generation circuitry, an example voltage comparator stage, an example delay comparator stage, and example offset voltage control circuitry.

FIG. 3 is a schematic diagram of the example reference generation circuitry of FIG. 2.

FIG. 4 is a block diagram of the example voltage comparator stage of FIG. 2 and the example delay comparator stage of FIG. 2.

FIGS. 5A, 5B, and 5C are plots of example operations of the example voltage comparator stage of FIGS. 2 and 4 and the example delay comparator stage of FIGS. 2 and 4.

FIG. 6 is a block diagram of example of the example voltage comparator stage of FIGS. 2 and 4 and another example of the delay comparator stage of FIGS. 2 and 4, the delay comparator stage further including an example voltage-controlled delay circuitry.

FIG. 7 is a schematic diagram of an example of the voltage-controlled delay circuitry of FIG. 6 and an example delay comparator.

FIG. 8 is a schematic diagram of an example of the offset voltage control circuitry of FIG. 2.

FIG. 9 is a flowchart representative of example machine-readable instructions or example operations that may be at least one of executed, instantiated, or performed using example implementations of the reference generation circuitry of FIGS. 2 and 3, the voltage comparator stage of FIGS. 2, 4, and 6, the delay comparator stage of FIGS. 2, 4, and 6, and the offset voltage control circuitry of FIG. 8, or more generally the FADC of FIGS. 1 and 2.

FIG. 10 is a block diagram of an example processing platform including programmable circuitry structured to execute, instantiate, or perform the example machine-readable instructions or perform the example operations of FIG. 9 to implement the FADC of FIG. 2.

FIG. 11 is a block diagram of an example implementation of the programmable circuitry of FIG. 10.

FIG. 12 is a block diagram of another example implementation of the programmable circuitry of FIG. 10.

The drawings are not necessarily to scale. Generally, the same reference numbers in the drawing(s) and this description refer to the same or similar (functionally and/or structurally) features and/or parts. Although the drawings show regions with clean lines and boundaries, some or all of these lines and boundaries may be idealized. In reality, the boundaries or lines may be unobservable, blended or irregular.

### DETAILED DESCRIPTION

An analog-to-digital converter (ADC) generates a digital output responsive to an analog input. Digital outputs of the ADC allow digital systems to perform digital signal processing operations using digital representations of an analog input signal. Some ADC circuitry implements a pipeline design to produce different portions of a digital value that represents the analog input signal. Pipeline designs include a plurality of sequential stages. The sequential stages respectively include a sub-ADC that produces a relatively low-resolution digital representation of the analog input. The sub-ADC, also referred to as a flash ADC (FADC), includes a series of comparators to compare the analog input to a series of reference voltages. The comparators produce sign bits representing the result of the comparison. Alignment and correction circuitry combines the sign bits from the FADCs of the pipeline stages to produce a relatively high-resolution digital representation of the analog input signal.

FADCs include reference generation circuitry and a plurality of voltage comparators. The reference generation circuitry generates a series of different reference voltages across the range of possible voltages of an analog input signal. Ideally, the reference voltages divide the range of possible voltages into equal segments. In some designs, the reference generation circuitry provides one of the reference voltages to each of the voltage comparators.

The voltage comparators compare the analog input signal to a respective one of the reference voltages. The output of the voltage comparators is referred to as a sign output or a sign bit. A voltage comparator sets the sign output to a logical one (e.g., a logic high) responsive to the analog input signal being greater than the reference voltage. The voltage comparator sets the sign output to a logical zero (e.g., a logic low) responsive to the analog input signal being less than the reference voltage. In operation, the voltage comparators produce sign outputs having a logical one state until the voltage of the reference voltages exceed the analog input signal. Once the reference voltages are greater than the analog input signal, the remaining voltage comparators set the sign outputs to a logical zero state. In such operations, the FADC represents the voltage of the analog input signal by the location of the transition of the state of the sign outputs from a logical one to a logical zero.

The digital resolution of the FADC corresponds to the number of voltage comparators. For example, a five-bit digital value can represent thirty-two different voltages of the analog input signal. In such an example, the FADC includes thirty-two voltage comparators that determine which of the thirty-two possible voltages represent the analog input signal. To support such a determination, the reference generation circuitry needs to generate thirty-two reference voltages representing the thirty-two possible voltages of the analog input. However, implementing such reference generation circuitry has a relatively large system-on-chip (SoC) size. Also, the size of the reference generation circuitry exponentially grows with the resolution of the FADC.

Some FADC designs reduce the number of reference voltages by utilizing two sequential voltage comparator stages. In the first voltage comparator stage, a reduced number of voltage comparators compare the analog input signal to a reduced number of reference voltages. The first voltage comparator stage provides the sign outputs to a second voltage comparator stage. In the second voltage comparator stage, additional voltage comparators that divide the reference voltages of corresponding voltage comparators of the first voltage comparator stage. For example, in a five-bit FADC, the first voltage comparator stage includes eight voltage comparators and the second voltage comparator stage includes twenty-four voltage comparators. The sign bits of the eight voltage comparators of the first voltage comparator stage are a coarse representation of analog input signal. The sign bits of the twenty-four voltage comparators of the second voltage comparator stage are a fine representation of the analog input signal between each of the sign bits of the first voltage comparator stage. For example, the first three sign bits of the second voltage comparator stage represent voltages between a first and second reference voltage of first and second voltage comparators of the first voltage comparator stage. In such an example, the second three sign bits of the second voltage comparator stage represent voltages between a third and fourth reference voltage of third and fourth voltage comparators of the first voltage comparator stage.

The multi-stage FADC reduces the SoC size of the reference generation circuitry by decreasing the number of reference voltages to the number of comparators in the first voltage comparator stage. However, adding a sequential stage of voltage comparators decreases the conversion speed of the FADC by having an additional voltage comparison. In pipeline ADCs, which may have multiple sequential FADCs, the decrease in the conversion speed compounds across the plurality of stages forming the pipeline design. Such changes in the conversion speed limit the possible implementations of multi-stage FADCs.

Examples described herein include example methods and apparatus to interpolate between voltages in a delay domain. In some described examples, an FADC includes reference generation circuitry, a voltage comparator stage, and a delay comparator stage. The reference generation circuitry provides reference voltages to the voltage comparator stage. The voltage comparator stage includes a plurality of voltages comparators. The voltage comparators compare the reference voltages to an analog input signal. The voltage comparators produce a sign output and a delay output responsive to the comparison of the reference voltage to the analog input signal. A voltage comparator sets the sign output to a logical one (e.g., a logic high) responsive to the analog input signal being greater than the reference voltage. The voltage comparator sets the sign output to a logical zero (e.g., a logic low) responsive to the analog input signal being less than the reference voltage. The voltage comparator sets the delay output to a logical one (e.g., logic high) at a time corresponding to the difference between the reference voltage and the analog input signal. For example, the voltage comparator quickly sets the delay output to a logical one responsive to a relatively large difference between the reference voltage and the analog input signal. In such an example, the voltage comparator delays setting the delay output as the difference between the reference voltage and the analog input signal decreases. The delay of the delay output is greatest when the reference voltage is approximately equal to the analog input signal. In such example operations, the proximity between reference voltage and the analog input signal controls a delay of the delay output. The voltage comparator stage provides the delay outputs of the voltage comparators to the delay comparator stage.

In such described examples, the delay comparator stage includes a plurality of delay comparators. The delay comparators compare the timing of edges of the delay outputs from two voltage comparators. A delay comparator sets a sign output to a logical one (e.g., a logic high) responsive to a rising edge of a first delay output occurring before a rising edge of a second delay output. The delay comparator sets the sign output to a logical zero (e.g., a logic low) responsive to the rising edge of the second delay output occurring before the rising edge of the second delay output. In example operations, the delay outputs of two voltage comparators are provided to at least one delay comparator. The sign output of the delay comparator represents the reference voltage being closer to the reference voltage of the first voltage comparator as a logical zero. The sign output of the delay comparator represents the reference voltage being closer to the reference voltage of the second voltage comparator as a logical one. Advantageously, the delay comparator interpolates a voltage threshold between the reference voltages of the first and second voltage comparators using the delay outputs.

In some described examples, a plurality of delay comparators are coupled to the same first and second voltage comparators. A first delay comparator interpolates a first threshold equally between the reference voltages of the first and second voltage comparators. A second delay comparator interpolates a second voltage threshold between the first interpolated voltage threshold and the reference voltage of the first voltage comparator. A third delay comparator interpolates a third voltage threshold between the first interpolated voltage threshold and the reference voltage of the second voltage comparator. In such examples, the second and third delay comparators bias at least one of the delay outputs to produce the second and third interpolated voltage thresholds. Advantageously, a plurality of delay comparators can interpolate any number of voltage thresholds between any two reference voltages of the voltage comparator stage using the delay outputs of the corresponding voltage comparators. Advantageously, the delay comparator stage increases the analog-to-digital conversion speed of the FADC responsive to interpolating using delay outputs of the voltage comparators.

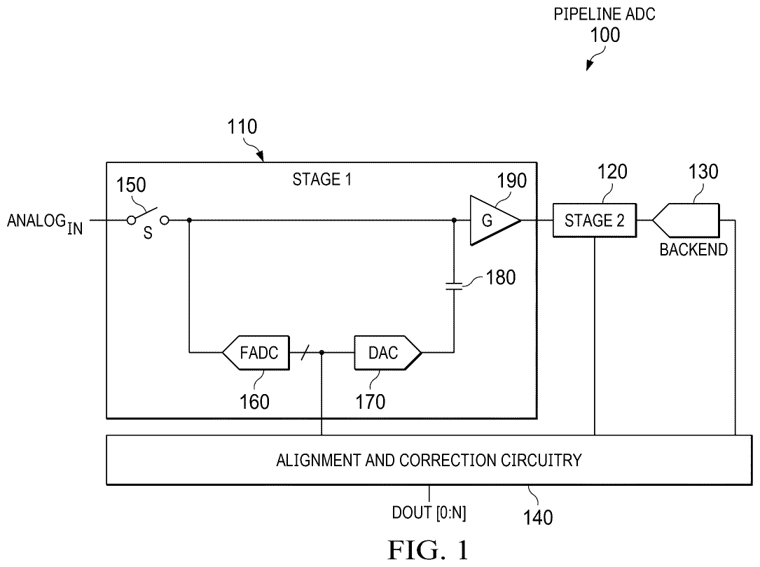

FIG. 1 is a block diagram of an example pipeline ADC 100. The pipeline ADC 100 of FIG. 1 includes first example stage circuitry 110, second example stage circuitry 120, example backend analog-to-digital converter (ADC) circuitry 130, and example alignment and correction circuitry 140. The stage circuitry 110 of FIG. 1 includes an example switch 150, an example FADC 160, an example digital-to-analog converter (DAC) 170, an example capacitor 180, and an example amplifier 190. In some examples, the stage circuitry 110 includes an additional switch coupling the output of the DAC 170 to a common terminal, which provides a common potential (e.g., ground, AVSS, etc.).

The pipeline ADC 100 has an input and an output. The input of the pipeline ADC 100 is structured to be coupled to an analog signal source. Such an analog signal source provides an analog input signal (ANALOG_{IN}) for conversion. The output of the pipeline ADC 100 is structured to be coupled to digital circuitry. The output of the pipeline ADC 100 provides a digital output (DOUT[0:N]), which represents analog values of the analog input signal (ANALOG_{IN}).

The stage circuitry 110 has an input, a first output, and a second output. The input of the stage circuitry 110 is coupled to the input of the pipeline ADC 100 (ANALOG_{IN}). The first output of the stage circuitry 110 is coupled to the alignment and correction circuitry 140. The second output of the stage circuitry 110 is coupled to the second stage circuitry 120.

The second stage circuitry 120 has an input, a first output, and a second output. The input of the second stage circuitry 120 is coupled to the stage circuitry 110. The first output of the second stage circuitry 120 is coupled to the alignment and correction circuitry 140. The second output of the second stage circuitry 120 is coupled to the backend ADC circuitry 130. The second stage circuitry 120 is another example of the stage circuitry 110. In some examples, the pipeline ADC 100 may include any number of instances of the stage circuitry 110, 120.

The backend ADC circuitry 130 has an input and an output. The input of the backend ADC circuitry 130 is coupled to the second stage circuitry 120. The output of the backend ADC circuitry 130 is coupled to the alignment and correction circuitry 140. In some examples, the backend ADC circuitry 130 is illustrated and described as an analog-to-digital converter.

The alignment and correction circuitry 140 has a first input, a second input, a third input, and an output. The first input of the alignment and correction circuitry 140 is coupled to the stage circuitry 110. The second input of the alignment and correction circuitry 140 is coupled to the second stage circuitry 120. The third input of the alignment and correction circuitry 140 is coupled to the backend ADC circuitry 130. The output of the alignment and correction circuitry 140 is coupled to the output of the pipeline ADC 100 (DOUT[0:N]).

The switch 150 has a first terminal and a second terminal. The first terminal of the switch 150 is coupled to the input of the pipeline ADC 100 (ANALOG_{IN}). The second terminal of the switch 150 is coupled to the FADC 160, the capacitor 180, and the amplifier 190. In some examples, the switch 150 is illustrated or described as a transistor, sample and hold circuitry, etc.

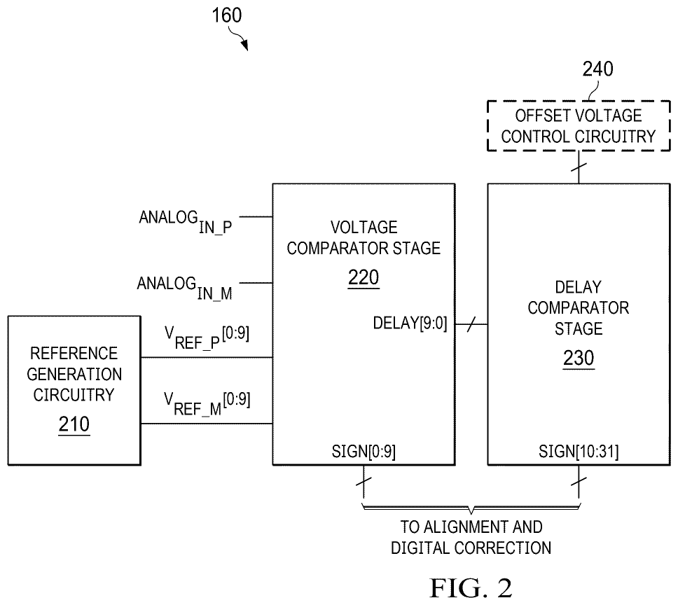

The FADC 160 has an input and an output. The input of the FADC 160 is coupled to the switch 150, the capacitor 180, and the amplifier 190. The output of the FADC 160 is coupled to the alignment and correction circuitry 140 and the DAC 170. In some examples, the FADC 160 is referred to as a sub-ADC or flash. An example of the FADC 160 is further illustrated and described in connection with FIG. 2.

The DAC 170 has an input and an output. The input of the DAC 170 is coupled to the alignment and correction circuitry 140 and the FADC 160. The output of the DAC 170 is coupled to the capacitor 180. In some examples, the DAC 170 is illustrated or described as a capacitor DAC, a resistor DAC, a resistor ladder, etc.

The capacitor 180 has a first terminal and a second terminal. The first terminal of the capacitor 180 is coupled to the DAC 170. The second terminal of the capacitor 180 is coupled to the switch 150, the FADC 160, and the amplifier 190.

The amplifier 190 has an input and an output. The input of the amplifier 190 is coupled to the switch 150, the FADC 160, and the capacitor 180. The output of the amplifier 190 is coupled to the second stage circuitry 120.

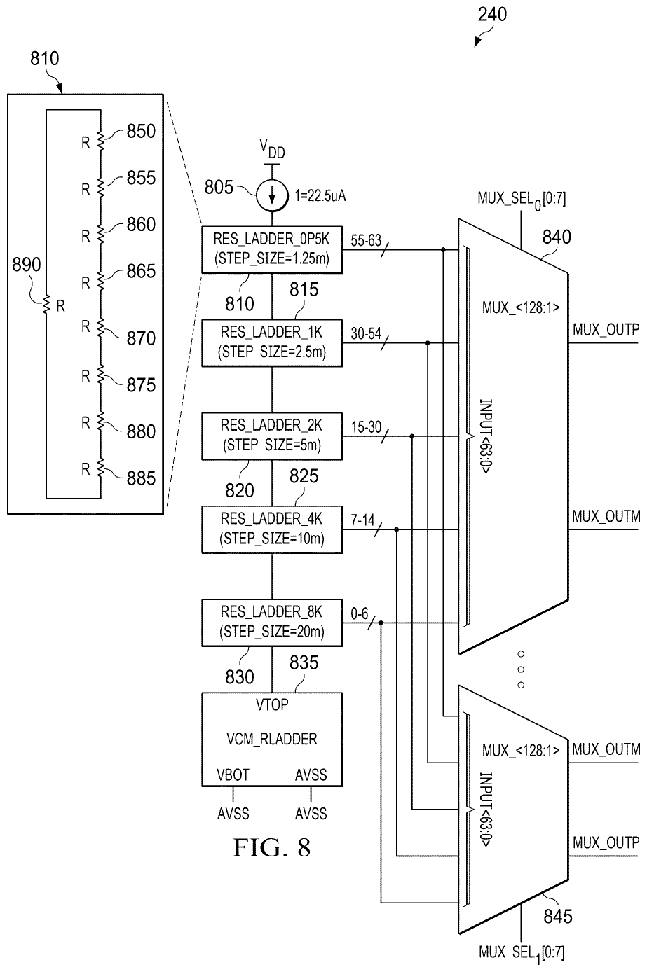

In example operation, an analog signal source provides the analog input signal (ANALOG_{IN}). In some examples, as illustrated in FIG. 2, the analog input signal (ANALOG_{IN}) is a differential pair of analog input signals. The switch 150 periodically closes to provide a sample of the analog input signal (ANALOG_{IN}) to the FADC 160 and charge a first plate of the capacitor 180. The FADC 160 produces a plurality of sign outputs responsive to a comparison of the analog input signal (ANALOG_{IN}) to reference voltages. Also, the FADC 160 interpolates voltage thresholds between the reference voltages to produce additional sign outputs. Advantageously, interpolating voltage thresholds decreases the number of reference voltages. Advantageously, interpolating voltage thresholds responsive to delays of voltage comparisons decreases the time of an additional conversion stage. Advantageously, decreasing the conversion time of the second conversion increases the conversion speed of the FADC 160. Example operations of the FADC 160 are further illustrated and described in connection with FIGS. 2 and 8.

In such example operations, the DAC 170 generates an analog approximation of the analog input signal (ANALOG_{IN}) responsive to the sign bits from the FADC 160. The DAC 170 provides the analog approximation of the analog input signal to the second terminal of the capacitor 180. The amplifier 190 amplifies the difference between the analog input signal and analog approximation responsive to the charge of the capacitor 180. The amplifier 190 provides the amplified voltage, also referred to as a residue voltage to the second stage circuitry 120. The second stage circuitry 120 generates second sign bits responsive to a conversion by another instance of the FADC 160. The second stage circuitry 120 provides a subsequent residue voltage to the backend ADC circuitry 130. The backend ADC circuitry 130 generates third sign bits responsive to an analog to digital conversion. The alignment and correction circuitry 140 aligns the sign outputs of the stage circuitry 110, 120 and the backend ADC circuitry 130 for the same sample of the analog input signal. The alignment and correction circuitry 140 provides a relatively high-resolution digital value responsive to the sign outputs.

FIG. 2 is a block diagram of the example FADC 160 of FIG. 1. The FADC 160 of FIG. 2 includes example reference generation circuitry 210, an example voltage comparator stage 220, an example delay comparator stage 230, and example offset voltage control circuitry 240. The FDAC 160 has a first input, a second input, first outputs, and second outputs. The first and second inputs of the FADC 160 (ANALOG_{IN_P}, ANALOG_{IN_M}) are structured to be coupled to the switch 150 of FIG. 1, the capacitor 180 of FIG. 1, and the amplifier 190 of FIG. 1. The first and second outputs of the FADC 160 (SIGN[0:31]) are structured to be coupled to the alignment and correction circuitry 140 of FIG. 1 and the DAC 170 of FIG. 1. Although in the example of FIG. 2, the FADC 160 is illustrated and described as having a five-bit resolution, the FADC 160 may be modified to support any resolution.

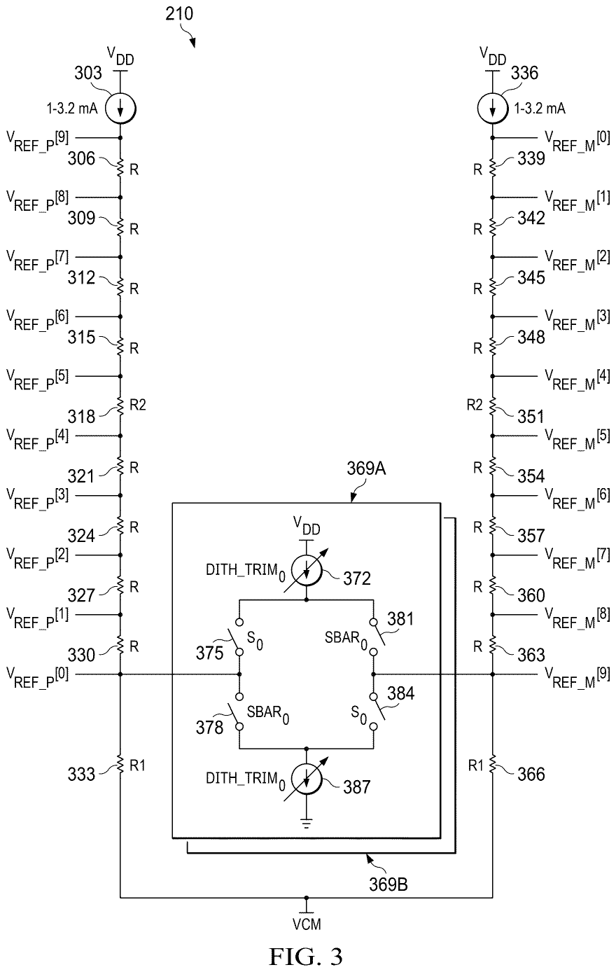

The reference generation circuitry 210 (also referred to as voltage reference generation circuitry) has first outputs and second outputs. The first and second outputs of the reference generation circuitry 210 (V_{REF_P}[0:9], V_{REF_M}[0:9]) are coupled to the voltage comparator stage 220. An example of the reference generation circuitry 210 is further illustrated and described in connection with FIG. 3. Although in the example of FIG. 2, the reference generation circuitry 210 is illustrated and described as having differential outputs, the reference generation circuitry 210 may be modified to have single-ended outputs.

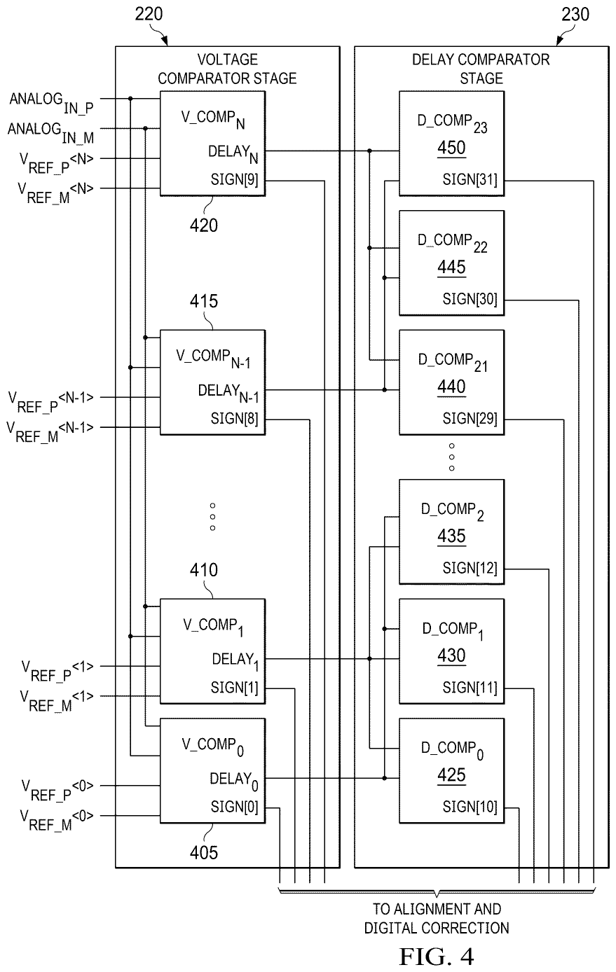

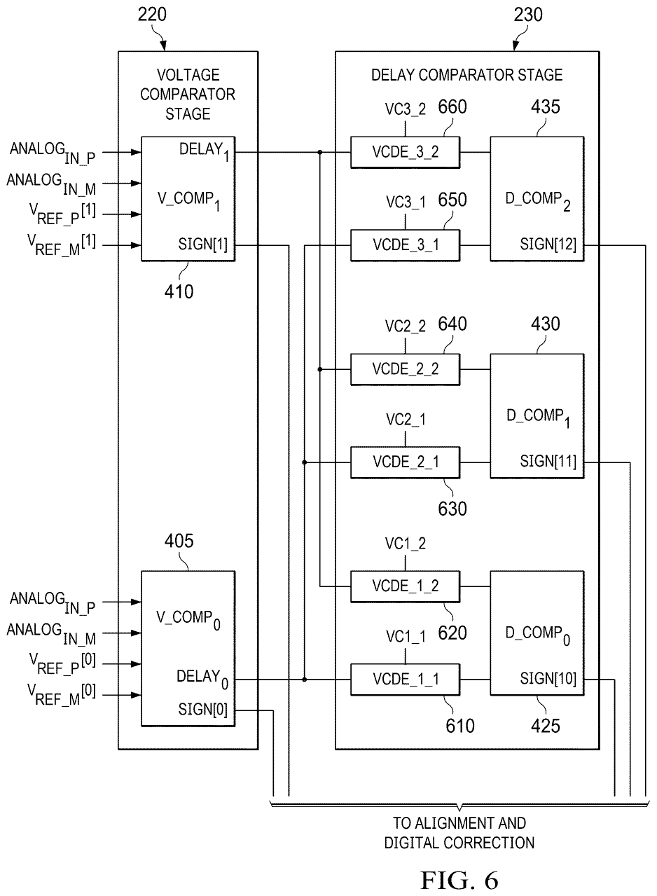

The voltage comparator stage 220 has a first input, a second input, a third input, a fourth input, first outputs, and second outputs. The first and second inputs of the voltage comparator stage 220 are coupled to the first and second inputs of the FADC 160 (ANALOG_{IN_P}, ANALOG_{IN_M}). The third and fourth inputs of the voltage comparator stage 220 are coupled to the reference generation circuitry 210 (V_{REF_P}[0:9], V_{REF_M}[0:9]). The first outputs of the voltage comparator stage 220 (also referred to as sign outputs) are coupled to the first outputs of the FADC 160 (SIGN[0:9]). The second outputs of the voltage comparator stage 220 (DELAY[0:N])(also referred to as delay outputs) are coupled to the delay comparator stage 230. Examples of the voltage comparator stage 220 are further illustrated and described in connection with FIGS. 4 and 6.

The delay comparator stage 230 has first inputs, second inputs, and outputs. The first inputs of the delay comparator stage 230 are coupled to the voltage comparator stage 220. The second inputs of the delay comparator stage 230 are coupled to the offset voltage control circuitry 240. The outputs of the delay comparator stage 230 are coupled to the second outputs of the FADC 160 (SIGN[10:31]). Examples of the delay comparator stage 230 are further illustrated and described in connection with FIGS. 4 and 6.

The offset voltage control circuitry 240 has an output coupled to the delay comparator stage 230. As illustrated by the dash outline, in some examples, the FADC 160 may not include the offset voltage control circuitry 240. Such an example is illustrated and described in connection with FIG. 4. An example of the offset voltage control circuitry 240 is further illustrated and described in connection with FIG. 8.

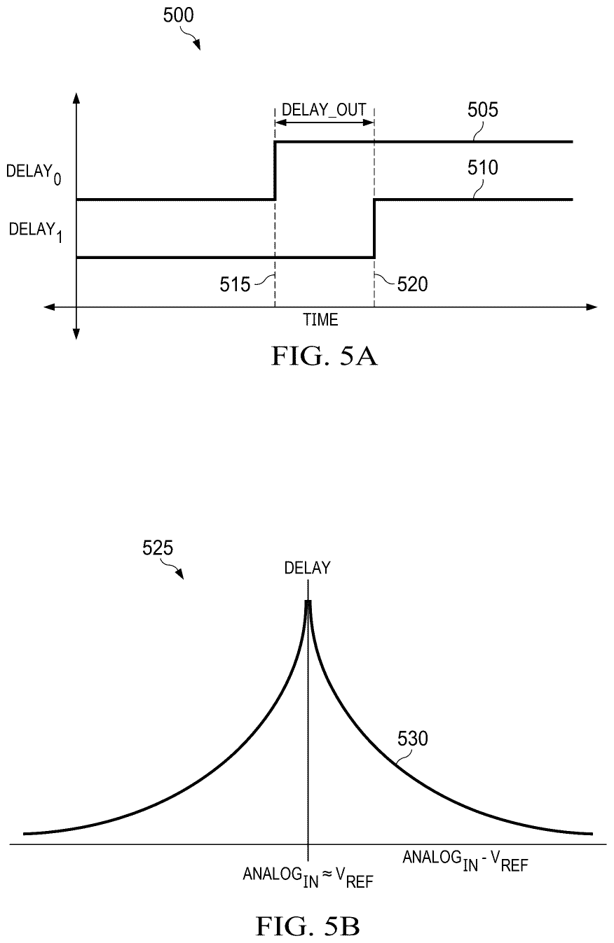

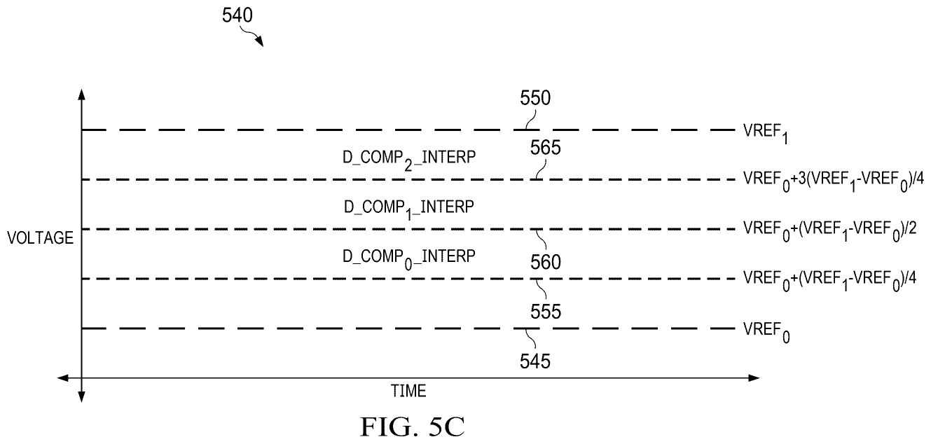

In example operation, the reference generation circuitry 210 generates a plurality of reference voltages (V_{REF}[0:9]). In some examples, the reference generation circuitry 210 generates differential reference voltages (V_{REF_P}[0:9], V_{REF_M}[0:9]). The reference generation circuitry 210 provides the reference voltages to the voltage comparator stage 220. The voltage comparator stage 220 compares the reference voltages to an analog input signal (ANALOG_{IN_P}, ANALOG_{IN_M}). The voltage comparator stage 220 generates a sign bit for the comparison of the analog input signal (ANALOG_{IN}) to each of the reference voltages. Also, the voltage comparator stage 220 generates a delay signal for the comparison of the analog input signal to each of the reference voltages. The voltage comparator stage 220 delays edges of the delay signals responsive to the proximity of the analog input signal to the reference voltage. Such delays are illustrated and described in connection with FIGS. 5A and 5B.

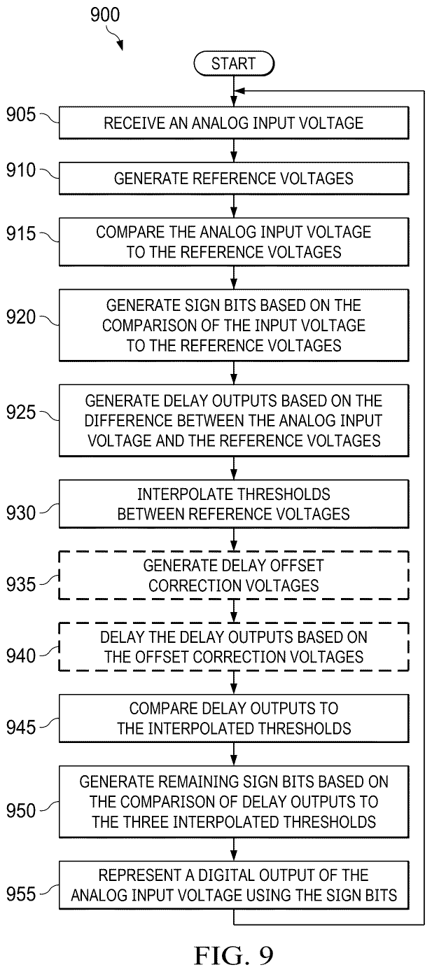

In such example operations, the delay comparator stage 230 generates sign bits responsive to the delays of the delay signals. For example, the delay comparator stage 230 sets a first sign bit to a logical one responsive to a first delay signal (Delay₀) having a rising edge before a second delay signal (Delay₁). In some examples, such as in FIGS. 4 and 6, the delay comparator stage 230 interpolates a plurality of threshold voltages between the reference voltages of the reference generation circuitry 210. For example, the delay comparator stage 230 interpolates three voltage thresholds between two reference voltages by producing three sign bits responsive to two delay signals. In some such examples, such as in FIG. 6, the delay comparator stage 230 includes circuitry to add additional delays to the delay signals responsive to voltages from the offset voltage control circuitry 240. Example operations of the FADC 160 are further illustrated and described in connection with FIG. 9. Advantageously, the delay comparator stage 230 interpolates additional voltages between reference voltages responsive to the delay signals from the voltage comparator stage 220.

FIG. 3 is a schematic diagram of the example reference generation circuitry 210 of FIG. 2. The reference generation circuitry 210 of FIG. 2 includes first example current source circuitry 303, a first example resistor 306, a second example resistor 309, a third example resistor 312, a fourth example resistor 315, a fifth example resistor 318, a sixth example resistor 321, a seventh example resistor 324, an eighth example resistor 327, a ninth example resistor 330, a tenth example resistor 333, second example current source circuitry 336, an eleventh example resistor 339, a twelfth example resistor 342, a thirteenth example resistor 345, a fourteenth example resistor 348, a fifteenth example resistor 351, a sixteenth example resistor 354, a seventeenth example resistor 357, an eighteenth example resistor 360, a nineteenth example resistor 363, a twentieth example resistor 366, and example offset circuitry 369A, 369B. The offset circuitry 369 of FIG. 3 includes first example current source circuitry 372, a first example switch 375, a second example switch 378, a third example switch 381, a fourth example switch 384, and second example current source circuitry 387. In some examples, as illustrated as the cascading blocks, the offset circuitry 369 is first offset circuitry 369A and the reference generation circuitry 210 further includes a plurality of instances of the offset circuitry 369, such as second offset circuitry 369B. The reference generation circuitry 210 has outputs (V_{REF_P}[0:9], V_{REF_M}[0:9]) structured to be coupled to the voltage comparator stage 220 of FIG. 2. Although in the example of FIG. 3, the reference generation circuitry 210 is illustrated and described as differential circuitry, in some examples, the reference generation circuitry 210 may be modified to be single-ended circuitry.

The current source circuitry 303 has a first terminal and a second terminal. The first terminal of the current source circuitry 303 is coupled to a supply terminal, which provides a supply voltage (e.g., V_{DD}, AVDD, etc.). The second terminal of the current source circuitry 303 is coupled to the resistor 306 and an output of the reference generation circuitry 210 (V_{REF_P}[9]).

The resistor 306 has a first terminal and a second terminal. The first terminal of the resistor 306 is coupled to the current source circuitry 303 and the output of the reference generation circuitry 210 (V_{REF_P}[9]). The second terminal of the resistor 306 is coupled to the resistor 309 and an output of the reference generation circuitry 210 (V_{REF_P}[8]).

The resistor 309 has a first terminal and a second terminal. The first terminal of the resistor 309 is coupled to the resistor 306 and the output of the reference generation circuitry 210 (V_{REF_P}[8]). The second terminal of the resistor 309 is coupled to the resistor 312 and an output of the reference generation circuitry 210 (V_{REF_P}[7]).

The resistor 312 has a first terminal and a second terminal. The first terminal of the resistor 312 is coupled to the resistor 309 and the output of the reference generation circuitry 210 (V_{REF_P}[7]). The second terminal of the resistor 312 is coupled to the resistor 315 and an output of the reference generation circuitry 210 (V_{REF_P}[6]).

The resistor 315 has a first terminal and a second terminal. The first terminal of the resistor 315 is coupled to the resistor 312 and the output of the reference generation circuitry 210 (V_{REF_P}[6]). The second terminal of the resistor 315 is coupled to the resistor 318 and an output of the reference generation circuitry 210 (V_{REF_P}[5]).

The resistor 318 has a first terminal and a second terminal. The first terminal of the resistor 318 is coupled to the resistor 315 and the output of the reference generation circuitry 210 (V_{REF_P}[5]). The second terminal of the resistor 318 is coupled to the resistor 321 and an output of the reference generation circuitry 210 (V_{REF_P}[4]).

The resistor 321 has a first terminal and a second terminal. The first terminal of the resistor 321 is coupled to the resistor 318 and the output of the reference generation circuitry 210 (V_{REF_P}[4]). The second terminal of the resistor 321 is coupled to the resistor 324 and an output of the reference generation circuitry 210 (V_{REF_P}[3]).

The resistor 324 has a first terminal and a second terminal. The first terminal of the resistor 324 is coupled to the resistor 321 and the output of the reference generation circuitry 210 (V_{REF_P}[3]). The second terminal of the resistor 324 is coupled to the resistor 327 and an output of the reference generation circuitry 210 (V_{REF_P}[2]).

The resistor 327 has a first terminal and a second terminal. The first terminal of the resistor 327 is coupled to the resistor 324 and the output of the reference generation circuitry 210 (V_{REF_P}[2]). The second terminal of the resistor 327 is coupled to the resistor 330 and an output of the reference generation circuitry 210 (V_{REF_P}[1]).

The resistor 330 has a first terminal and a second terminal. The first terminal of the resistor 330 is coupled to the resistor 327 and the output of the reference generation circuitry 210 (V_{REF_P}[1]). The second terminal of the resistor 330 is coupled to the resistor 333, the offset circuitry 369, and an output of the reference generation circuitry 210 (V_{REF_P}[0]).

The resistor 333 has a first terminal and a second terminal. The first terminal of the resistor 333 is coupled to the resistor 330, the offset circuitry 369, and the output of the reference generation circuitry 210 (V_{REF_P}[0]). The second terminal of the resistor 333 is coupled to a common terminal, which provides a common potential (e.g., ground, AVSS, VCM, etc.).

The current source circuitry 336 has a first terminal and a second terminal. The first terminal of the current source circuitry 336 is coupled to the supply terminal, which provides the supply voltage. The second terminal of the current source circuitry 336 is coupled to the resistor 339 and an output of the reference generation circuitry 210 (V_{REF_M}[0]).

The resistor 339 has a first terminal and a second terminal. The first terminal of the resistor 339 is coupled to the current source circuitry 336 and the output of the reference generation circuitry 210 (V_{REF_M}[0]). The second terminal of the resistor 339 is coupled to the resistor 342 and an output of the reference generation circuitry 210 (V_{REF_M}[1]).

The resistor 342 has a first terminal and a second terminal. The first terminal of the resistor 342 is coupled to the resistor 339 and the output of the reference generation circuitry 210 (V_{REF_M}[1]). The second terminal of the resistor 342 is coupled to the resistor 345 and an output of the reference generation circuitry 210 (V_{REF_M}[2]).

The resistor 345 has a first terminal and a second terminal. The first terminal of the resistor 345 is coupled to the resistor 342 and the output of the reference generation circuitry 210 (V_{REF_M}[2]). The second terminal of the resistor 345 is coupled to the resistor 348 and an output of the reference generation circuitry 210 (V_{REF_M}[3]).

The resistor 348 has a first terminal and a second terminal. The first terminal of the resistor 348 is coupled to the resistor 345 and the output of the reference generation circuitry 210 (V_{REF_M}[3]). The second terminal of the resistor 348 is coupled to the resistor 351 and an output of the reference generation circuitry 210 (V_{REF_M}[4]).

The resistor 351 has a first terminal and a second terminal. The first terminal of the resistor 351 is coupled to the resistor 348 and the output of the reference generation circuitry 210 (V_{REF_M}[4]). The second terminal of the resistor 351 is coupled to the resistor 354 and an output of the reference generation circuitry 210 (V_{REF_M}[5]).

The resistor 354 has a first terminal and a second terminal. The first terminal of the resistor 354 is coupled to the resistor 351 and the output of the reference generation circuitry 210 (V_{REF_M}[5]). The second terminal of the resistor 354 is coupled to the resistor 357 and an output of the reference generation circuitry 210 (V_{REF_M}[6]).

The resistor 357 has a first terminal and a second terminal. The first terminal of the resistor 357 is coupled to the resistor 354 and the output of the reference generation circuitry 210 (V_{REF_M}[6]). The second terminal of the resistor 357 is coupled to the resistor 360 and an output of the reference generation circuitry 210 (V_{REF_M}[7]).

The resistor 360 has a first terminal and a second terminal. The first terminal of the resistor 360 is coupled to the resistor 357 and the output of the reference generation circuitry 210 (V_{REF_M}[7]). The second terminal of the resistor 360 is coupled to the resistor 363 and an output of the reference generation circuitry 210 (V_{REF_M}[8]).

The resistor 363 has a first terminal and a second terminal. The first terminal of the resistor 363 is coupled to the resistor 360 and the output of the reference generation circuitry 210 (V_{REF_M}[8]). The second terminal of the resistor 363 is coupled to the resistor 366, the offset circuitry 369, and an output of the reference generation circuitry 210 (V_{REF_M}[9]).

The resistor 366 has a first terminal and a second terminal. The first terminal of the resistor 366 is coupled to the resistor 363, the offset circuitry 369, and the output of the reference generation circuitry 210 (V_{REF_M}[9]). The second terminal of the resistor 366 is coupled to the common terminal, which provides the common potential.

The offset circuitry 369 has a first terminal and a second terminal. The first terminal of the offset circuitry 369 is coupled to the resistors 330, 333 and the output of the reference generation circuitry 210 (V_{REF_P}[0]). The second terminal of the offset circuitry 369 is coupled to the resistors 363, 366 and the output of the reference generation circuitry 210 (V_{REF_M}[9]).

The current source circuitry 372 has a first terminal, a second terminal, and a control input. The first terminal of the current source circuitry 372 is coupled to the supply terminal, which provides the supply voltage. The second terminal of the current source circuitry 372 is coupled to the switches 375, 381. The control input of the current source circuitry 372 receives a first trim code (DITH_TRIM₀). The trim code sets the magnitude of current from the current source circuitry 372.

The switch 375 has a first terminal, a second terminal, and a control input. The first terminal of the switch 375 is coupled to the current source circuitry 372 and the switch 381. The second terminal of the switch 375 is coupled to the resistors 330, 333, the switch 378, and the output of the reference generation circuitry 210 (V_{REF_P}[0]). The control input of the switch 375 receives a switch control signal (S).

The switch 378 has a first terminal, a second terminal, and a control input. The first terminal of the switch 378 is coupled to the resistors 330, 333, the switch 378, and the output of the reference generation circuitry 210 (V_{REF_P}[0]). The second terminal of the switch 378 is coupled to the switch 384 and the current source circuitry 387. The control input of the switch 378 receives an inverted switch control signal (SBAR).

The switch 381 has a first terminal, a second terminal, and a control input. The first terminal of the switch 381 is coupled to the current source circuitry 372 and the switch 375. The second terminal of the switch 381 is coupled to the resistors 363, 366, the switch 384, and the output of the reference generation circuitry 210 (V_{REF_M}[9]). The control input of the switch 381 receives the inverted switch control signal (SBAR).

The switch 384 has a first terminal, a second terminal, and a control input. The first terminal of the switch 384 is coupled to the resistors 363, 366, the switch 381, and the output of the reference generation circuitry 210 (V_{REF_M}[9]). The second terminal of the switch 384 is coupled to the switch 378 and the current source circuitry 387. The control input of the switch 384 receives the switch control signal (S).

The current source circuitry 387 has a first terminal, a second terminal, and a control input. The first terminal of the current source circuitry 387 is coupled to the switches 378, 384. The second terminal of the current source circuitry 387 is coupled to the common terminal, which provides the common potential. The control input of the current source circuitry 387 receives a second trim code (DITH_TRIM₀) The trim code sets the magnitude of current from the current source circuitry 387.

In example operations, the resistors 306, 309, 312, 315, 318, 321, 324, 327, 330 generate plus reference voltages (V_{REF_P}[0:9]) responsive to current from the current source circuitry 303. Similarly, the resistors 339, 342, 345, 348, 351, 354, 357, 360, 363 generate minus reference voltages (V_{REF_M}[0:9]) responsive to current from the current source circuitry 336. In the example of FIG. 3, the plus and minus reference voltages form a differential representation of reference voltages (V_{REF}[0:9]). The reference generation circuitry 210 of FIG. 3 provides the reference voltages to the voltage comparator stage 220. Advantageously, the current source circuitry 303, 336 control the reference voltages.

In such example operations, the offset circuitry 369 supplies or sinks additional current from the resistors 306, 309, 312, 315, 318, 321, 324, 327, 330, 339, 342, 345, 348, 351, 354, 357, 360, 363. In some examples, the switch control signal (S) closes the switches 375, 384 and the inverted switch control signal (SBAR) opens the switches 378, 381 to supply current to the resistor 333 and sink current from the resistor 363. In such examples, the offset circuitry 369 increases the common mode voltage of the reference voltages. In another example, the switch control signal (S) opens the switches 375, 384 and the inverted switch control signal (SBAR) closes the switches 378, 381 to sink current from the resistor 333 and supply current to the resistor 363. In such examples, the offset circuitry 369 decreases the common mode voltage of the reference voltages. Advantageously, the current from the current source circuitry 372, 387 shifts the common mode voltage of the reference voltages. Advantageously, the trim codes (DITH_TRIM₀) allow designers to improve the linearity of the reference voltages. Example operations of the reference generation circuitry 210 are further illustrated and described in connection with FIG. 9.

In some example operations, the offset circuitry 369 intentionally offsets the common mode voltage to allow the alignment and correction circuitry 140 to determine an error of the FADC 160. In these examples, the offset circuitry 369 is first offset circuitry 369A and the reference generation circuitry 210 further includes second offset circuitry 369B. In such examples, the first offset circuitry 369A receives a first switch control signal (S₀), a first inverted switch control signal (SBAR₀), and a first trim code (DITH_TRIM₀). The second offset circuitry 369B receives a second switch control signal (S₁), a second inverted switch control signal (SBAR₁), and a second trim code (DITH_TRIM₁). In such example operations, the offset circuitry 369A, 369B produce a error determination offset responsive to receiving different switch control signals and trim codes. For example, the first offset circuitry 369A increases the common mode voltage by a first value and the second offset circuitry 369B decreases the common mode voltage by a second value.

In such example operations, during a first portion of a sample cycle, the offset circuitry 369A, 369B offset the common mode voltage by the subtraction of the first and second values. During the first portion of the sample cycle, the voltage comparator stage 220 and the delay comparator stage 230 provide sign bits representing the analog input signal and the offset common mode. The digital alignment and correction circuitry 140 determines the sign bits during the first portion of the sample cycle to be first sign bits. During a second portion of the sample cycle, the first and second switch control signals open the switches 375, 378, 381, 384, which removes the offset of the offset circuitry 369A, 369B. The voltage comparator stage 220 and the delay comparator stage 230 provide sign bits representing the analog input signal without the offset common mode voltage. The digital alignment and correction circuitry 140 determines the sign bits during the second portion of the sample cycle to be second sign bits. The alignment and correction circuitry 140 determines an actual common mode offset using differences between the first and second sign bits. The alignment and correction circuitry 140 determines an error of the FADC 160 responsive to comparing the actual common mode offset to the offset represented by the first and second trim values. Advantageously, the alignment and correction circuitry 140 may determine and correct for error of the FADC 160 using the offset correction circuitry 369.

FIG. 4 is a block diagram of the example voltage comparator stage 220 of FIG. 2 and the example delay comparator stage 230 of FIG. 2. The voltage comparator stage 220 of FIG. 4 includes a first example voltage comparator 405, a second example voltage comparator 410, a third example voltage comparator 415, and a fourth example voltage comparator 420. The delay comparator stage 230 of FIG. 4 includes a first example delay comparator 425, a second example delay comparator 430, a third example delay comparator 435, a fourth example delay comparator 440, a fifth example delay comparator 445, and a sixth example delay comparator 450.

The voltage comparator stage 220 has first inputs, second inputs, first outputs, and second outputs. The first inputs of the voltage comparator stage 220 are structured to be coupled to an analog signal source. The first inputs of the voltage comparator stage 220 receive an analog input signal (ANALOG_{IN_P}, ANALOG_{IN_M}). The second inputs of the voltage comparator stage 220 are structured to be coupled to the reference generation circuitry 210 of FIGS. 2 and 3. The second inputs of the voltage comparator stage 220 receive reference voltages (V_{REF_P}[0:N], V_{REF_M}[0:N]). The first outputs of the voltage comparator stage 220 are structured to be coupled to the alignment and correction circuitry 140 of FIG. 1. The first outputs of the voltage comparator stage 220 provide first sign bits (SIGN[0:9]). The second outputs (also referred to as delay outputs) of the voltage comparator stage 220 are coupled to the delay comparator stage 230.

The delay comparator stage 230 has inputs and outputs. The inputs of the delay comparator stage 230 are coupled to the voltage comparator stage 220. The outputs of the delay comparator stage 230 are structured to be coupled to the alignment and correction circuitry 140. The outputs of the delay comparator stage 230 provide second sign bits (SIGN[10:31]). Another example of the delay comparator stage 230 is illustrated and described in connection with FIG. 6.

The voltage comparator 405 has a first input, a second input, a third input, a fourth input, a first output, and a second output. The first and second inputs of the voltage comparator 405 are coupled to respective ones of the first inputs of the voltage comparator stage 220 (ANALOG_{IN_P}, ANALOG_{IN_M}). The second and third inputs of the voltage comparator 405 are coupled to respective ones of the second inputs of the voltage comparator stage 220 (V_{REF_P}[0], V_{REF_M}[0]). The first output of the voltage comparator 405 is coupled to a first one of the outputs of the voltage comparator stage 220 (SIGN[0]). The second output of the voltage comparator 405 (DELAY₀) is coupled to the delay comparators 425, 430, 435.

The voltage comparator 410 has a first input, a second input, a third input, a fourth input, a first output, and a second output. The first and second inputs of the voltage comparator 410 are coupled to respective ones of the first inputs of the voltage comparator stage 220 (ANALOG_{IN_P}, ANALOG_{IN_M}). The second and third inputs of the voltage comparator 410 are coupled to respective ones of the second inputs of the voltage comparator stage 220 (V_{REF_P}[1], V_{REF_M}[1]). The first output of the voltage comparator 410 is coupled to a second one of the outputs of the voltage comparator stage 220 (SIGN[1]). The second output of the voltage comparator 410 (DELAY₁) is coupled to the delay comparators 425, 430, 435.

The voltage comparator 415 has a first input, a second input, a third input, a fourth input, a first output, and a second output. The first and second inputs of the voltage comparator 415 are coupled to respective ones of the first inputs of the voltage comparator stage 220 (ANALOG_{IN_P}, ANALOG_{IN_M}). The second and third inputs of the voltage comparator 415 are coupled to respective ones of the second inputs of the voltage comparator stage 220 (V_{REF_P}[N−1], V_{REF_M}[N−1]). The first output of the voltage comparator 405 is coupled to a third one of the outputs of the voltage comparator stage 220 (SIGN[8]). The second output of the voltage comparator 415 (DELAY_{N-1}) is coupled to the delay comparators 440, 445, 450.

The voltage comparator 420 has a first input, a second input, a third input, a fourth input, a first output, and a second output. The first and second inputs of the voltage comparator 420 are coupled to respective ones of the first inputs of the voltage comparator stage 220 (ANALOG_{IN_P}, ANALOG_{IN_M}). The second and third inputs of the voltage comparator 420 are coupled to respective ones of the second inputs of the voltage comparator stage 220 (V_{REF_P}[N], V_{REF_M}[N]). The first output of the voltage comparator 420 is coupled to a fourth one of the outputs of the voltage comparator stage 220 (SIGN[9]). The second output of the voltage comparator 420 (DELAY_{N}) is coupled to the delay comparators 440, 445, 450.

The delay comparator 425 has a first input, a second input, and an output. The first input of the delay comparator 425 is coupled to the voltage comparator 405 and the delay comparators 430, 435. The second input of the delay comparator 425 is coupled to the voltage comparator 410 and the delay comparators 430, 435. The output of the delay comparator 425 is coupled to a first one of the outputs of the delay comparator stage 230 (SIGN[10]).

The delay comparator 430 has a first input, a second input, and an output. The first input of the delay comparator 430 is coupled to the voltage comparator 405 and the delay comparators 425, 435. The second input of the delay comparator 430 is coupled to the voltage comparator 410 and the delay comparators 425, 435. The output of the delay comparator 430 is coupled to a second one of the outputs of the delay comparator stage 230 (SIGN[11]).

The delay comparator 435 has a first input, a second input, and an output. The first input of the delay comparator 435 is coupled to the voltage comparator 405 and the delay comparators 425, 430. The second input of the delay comparator 435 is coupled to the voltage comparator 410 and the delay comparators 425, 430. The output of the delay comparator 435 is coupled to a third one of the outputs of the delay comparator stage 230 (SIGN[12]).

The delay comparator 440 has a first input, a second input, and an output. The first input of the delay comparator 440 is coupled to the voltage comparator 415 and the delay comparators 445, 450. The second input of the delay comparator 440 is coupled to the voltage comparator 420 and the delay comparators 445, 450. The output of the delay comparator 440 is coupled to a fourth one of the outputs of the delay comparator stage 230 (SIGN[29]).

The delay comparator 445 has a first input, a second input, and an output. The first input of the delay comparator 445 is coupled to the voltage comparator 415 and the delay comparators 440, 450. The second input of the delay comparator 445 is coupled to the voltage comparator 420 and the delay comparators 440, 450. The output of the delay comparator 445 is coupled to a fifth one of the outputs of the delay comparator stage 230 (SIGN[30]).

The delay comparator 450 has a first input, a second input, and an output. The first input of the delay comparator 450 is coupled to the voltage comparator 415 and the delay comparators 440, 445. The second input of the delay comparator 450 is coupled to the voltage comparator 420 and the delay comparators 440, 445. The output of the delay comparator 450 is coupled to a sixth one of the outputs of the delay comparator stage 230 (SIGN[31]).

FIG. 5A is a timing diagram 500 of delay example operations of the example voltage comparator stage 220 of FIGS. 2 and 4. The example timing diagram 500 of FIG. 5A includes a first example delay signal 505 (DELAY₀) and a second example delay signal 510 (DELAY₁). The delay signal 505 illustrates a delay output of the voltage comparator 405 of FIG. 4 over time. The delay signal 510 illustrates a delay output of the voltage comparator 410 of FIG. 4 over time.

In example operations, the voltage comparator 405 compares a first reference voltage (V_{REF}[0]) to the analog input signal (ANALOG_{IN}). Similarly, the voltage comparator 410 compares a second reference voltage (V_{REF}[1]) to the analog input signal (ANALOG_{IN}). The voltage comparator 405 generates a sign output responsive to a determination of if the first reference voltage is greater than the analog input signal. For example, the voltage comparator 405 sets the state of the sign bit to a logical one responsive to the first reference voltage being greater than the analog input signal. The voltage comparator 410 generates a sign output responsive to a determination of if the second reference voltage is greater than the analog input signal. For example, the voltage comparator 410 sets the state of the sign bit to a logical one responsive to the second reference voltage being greater than the analog input signal.

In such example operations, the voltage comparators 405, 410 also generate the delay signals 505, 510. The voltage comparators 405, 410 delay edges of the delay signals 505, 510 responsive to a proximity of the analog input signal to the first and second reference voltages. For example, at a first time 515, the voltage comparator 405 generates a rising edge of the delay signal 505 and at a second time 520, the voltage comparator 410 generates a rising edge of the delay signal 510. In such examples, the difference between the times 515, 520 (DELAY_OUT) correspond to the difference in proximity of the analog input signal to the first reference voltage opposed to the second reference voltage.

FIG. 5B is a plot 525 of example delay operations of the example voltage comparator stage 220 of FIGS. 2 and 4. The example plot 525 of FIG. 5B includes example delays 530. The delays 530 illustrates the voltage comparators 405, 410, 415, 420 of FIG. 4 delay of edges of the delay signals (e.g., the delay signals 505, 510) across different proximities of the analog input signal (ANALOG_{IN}) to a reference voltage (V_{REF}).

In example operations, the voltage comparators 405, 410, 415, 420 delay edges of the delay signals by a longer time as the analog input signal approaches a corresponding reference voltage. The delays 530 of the voltage comparators 405, 410, 415, 420 decreases as the difference between the analog input signal and the reference voltage increases. As such, in the example of FIG. 5A, the analog input signal is close to the reference voltage of the voltage comparator 410 responsive to the delay of the delay signal 510 being greater than the delay of the delay signal 505. Similarly, the delays of the delay signals from the voltage comparators 415, 420 represent the proximity of the analog input signal to the corresponding reference voltages.

FIG. 5C is a plot 540 of example voltage interpolation operations of the delay comparator stage 230 of FIGS. 2 and 4. The example plot 540 of FIG. 5C illustrates a first example reference voltage 545, a second example reference voltage 550, a first example interpolated threshold voltage 555, a second example interpolated threshold voltage 560, and a third example interpolated threshold voltage 565.

The reference voltage 545 represents the threshold of the comparison by the voltage comparator 405. For example, the voltage comparator 405 sets the first sign bit to a logical one if the analog input signal is greater than the reference voltage 545. In such an example, the voltage comparator 405 sets the first sign bit to a logical zero if the analog input signal is less than the reference voltage 545.

The reference voltage 550 represents the threshold of the comparison by the voltage comparator 410. For example, the voltage comparator 410 sets the second sign bit to a logical one if the analog input signal is greater than the reference voltage 550. In such an example, the voltage comparator 410 sets the second sign bit to a logical zero if the analog input signal is less than the reference voltage 550.

The interpolated threshold voltage 555 represents a threshold of the comparison by the delay comparator 425. For example, the delay comparator 425 sets a third sign bit to a logical one if the analog input signal is greater than the interpolated threshold voltage 555. In example operations, the voltage comparators 405, 410 delay the delay signals by a first and second delay responsive to a voltage of greater than the interpolated threshold voltage 555. In such example operations, the delay comparator 425 sets the third sign bit to a logical one responsive to the first and second delays. In some examples, as further described below, the sizing of the delay comparator 425 may be modified to bias the first and second delay signals (Delay₀, Delay₁). Such biasing adjusts the interpolated threshold voltage 555.

The interpolated threshold voltage 560 represents a threshold of the comparison by the delay comparator 430. For example, the delay comparator 430 sets a fourth sign bit to a logical one if the analog input signal (ANALOG_{IN}) is greater than the interpolated threshold voltage 560. The interpolated threshold voltage 565 represents a threshold of the comparison by the delay comparator 435. For example, the delay comparator 435 sets a fifth sign bit to a logical one if the analog input signal (ANALOG_{IN}) is greater than the interpolated threshold voltage 565. In the example of FIG. 5C, the delay comparators 425, 430, 435 are structured to have the interpolated threshold voltages 555, 560, 565 evenly divide the difference between the reference voltages 545, 550. Alternatively, any number of delay comparators may divide the difference between any two reference voltages by any number of interpolated threshold voltages. Example operations of the voltage comparator stage 220 and the delay comparator stage 230 are further illustrated and described in connection with FIG. 9.

FIG. 6 is a block diagram of another example of the example voltage comparator stage 220 of FIGS. 2 and 4 and the example delay comparator stage 230 of FIGS. 2 and 4. The voltage comparator stage 220 of FIG. 6 includes the voltage comparators 405, 410 of FIG. 4. The delay comparator stage 230 of FIG. 6 includes the delay comparators 425, 430, 435, a first example voltage-controlled delay circuitry 610, a second example voltage-controlled delay circuitry 620, a third example voltage-controlled delay circuitry 630, a fourth example voltage-controlled delay circuitry 640, a fifth example voltage-controlled delay circuitry 650, and a sixth example voltage-controlled delay circuitry 660.

The voltage-controlled delay circuitry 610 has a first input, a second input, and an output. The first input of the voltage-controlled delay circuitry 610 is coupled to the voltage comparator 405 and the delay comparators 430, 435. The second input of the voltage-controlled delay circuitry 610 is structured to be coupled to the offset voltage control circuitry 240 (VC1_1). The output of the voltage-controlled delay circuitry 610 is coupled to the delay comparator 425.

The voltage-controlled delay circuitry 620 has a first input, a second input, and an output. The first input of the voltage-controlled delay circuitry 620 is coupled to the voltage comparator 410 and the delay comparators 430, 435. The second input of the voltage-controlled delay circuitry 620 is structured to be coupled to the offset voltage control circuitry 240 (VC1_2). The output of the voltage-controlled delay circuitry 620 is coupled to the delay comparator 425.

The voltage-controlled delay circuitry 630 has a first input, a second input, and an output. The first input of the voltage-controlled delay circuitry 630 is coupled to the voltage comparator 405 and the delay comparators 425, 435. The second input of the voltage-controlled delay circuitry 630 is structured to be coupled to the offset voltage control circuitry 240 (VC2_1). The output of the voltage-controlled delay circuitry 630 is coupled to the delay comparator 430.

The voltage-controlled delay circuitry 640 has a first input, a second input, and an output. The first input of the voltage-controlled delay circuitry 640 is coupled to the voltage comparator 410 and the delay comparators 425, 435. The second input of the voltage-controlled delay circuitry 640 is structured to be coupled to the offset voltage control circuitry 240 (VC2_2). The output of the voltage-controlled delay circuitry 640 is coupled to the delay comparator 430.

The voltage-controlled delay circuitry 650 has a first input, a second input, and an output. The first input of the voltage-controlled delay circuitry 650 is coupled to the voltage comparator 405 and the delay comparators 425, 430. The second input of the voltage-controlled delay circuitry 650 is structured to be coupled to the offset voltage control circuitry 240 (VC3_1). The output of the voltage-controlled delay circuitry 650 is coupled to the delay comparator 435.

The voltage-controlled delay circuitry 660 has a first input, a second input, and an output. The first input of the voltage-controlled delay circuitry 660 is coupled to the voltage comparator 410 and the delay comparators 425, 430. The second input of the voltage-controlled delay circuitry 660 is structured to be coupled to the offset voltage control circuitry 240 (VC3_2). The output of the voltage-controlled delay circuitry 660 is coupled to the delay comparator 435.

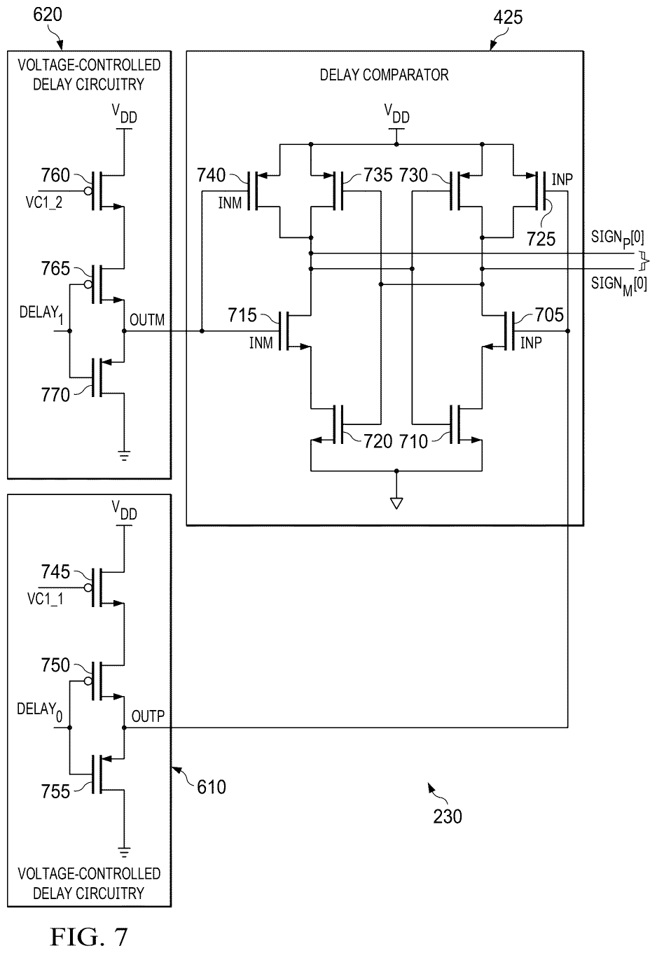

In example operations, the offset voltage control circuitry 240 provides a plurality of control voltages (VC1_1, VC1_2, VC2_1, VC2_2, VC3_1, VC3_2). The voltage-controlled delay circuitry 610, 620, 630, 640, 650, 660 delay the propagation of the delay signals from the outputs of the voltage comparators 405, 410 responsive to respective ones of the control voltages. In some examples, the voltage-controlled delay circuitry 610, 620, 630, 640, 650, 660 allows the offset voltage control circuitry 240 to bias the delay comparison of the delay comparators 425, 430, 435. For example, the delay comparator 425 represents the interpolated threshold voltage 555 of FIG. 5C responsive to increasing the delay of the voltage-controlled delay circuitry 620 and decreasing the delay of the voltage-controlled delay circuitry 610. Alternatively, as further described below, the sizing of transistors of the delay comparator 425 produces the same interpolated threshold voltage. In such examples, the voltage-controlled delay circuitry 610, 620, 630, 640, 650, 660 allow designers to account for manufacturing errors in the sizing of the delay comparators 425, 430, 435. Advantageously, the voltage-controlled delay circuitry 610, 620, 630, 640, 650, 660 allow the offset voltage control circuitry 240 to trim the interpolated threshold voltages 555, 560, 565 of FIG. 5C. Example operations of the voltage-controlled delay circuitry 610, 620, 630, 640, 650, 660 are further illustrated and described in connection with FIGS. 7 and 9.

FIG. 7 is a schematic diagram of the example delay comparator 425 of FIGS. 4 and 6 and examples of the voltage-controlled delay circuitries 610, 620 of FIG. 6. The delay comparator 425 of FIG. 8 includes a first example transistor 705, a second example transistor 710, a third example transistor 715, a fourth example transistor 720, a fifth example transistor 725, a sixth example transistor 730, a seventh example transistor 735, and an eighth example transistor 740. The voltage-controlled delay circuitry 610 of FIG. 8 includes a first example transistor 745, a second example transistor 750, and a third example transistor 755. The voltage-controlled delay circuitry 620 of FIG. 8 includes a first example transistor 760, a second example transistor 765, and a third example transistor 770.

The transistor 705 has a first terminal, a second terminal, and a control terminal. The first terminal of the transistor 705 is coupled to the transistors 720, 725, 730, 735 and the second output of the delay comparator 425 (SIGN_{M}[0]). The second terminal of the transistor 705 is coupled to the transistor 710. The control terminal of the transistor 705 is coupled to the transistor 725 and the voltage-controlled delay circuitry 610 (OUTP).

The transistor 710 has a first terminal, a second terminal, and a control terminal. The first terminal of the transistor 710 is coupled to the transistor 705. The second terminal of the transistor 710 is coupled to a common terminal, which provides a common potential (e.g., ground, AVSS, etc.). The control terminal of the transistor 710 is coupled to the transistors 715, 730, 735, 740 and the first output of the delay comparator 425 (SIGN_{P}[0]).

The transistor 715 has a first terminal, a second terminal, and a control terminal. The first terminal of the transistor 715 is coupled to the transistors 710, 730, 735, 740 and the first output of the delay comparator 425 (SIGN_{P}[0]). The second terminal of the transistor 715 is coupled to the transistor 720. The control terminal of the transistor 715 is coupled to the transistor 740 and the voltage-controlled delay circuitry 620 (OUTM).

The transistor 720 has a first terminal, a second terminal, and a control terminal. The first terminal of the transistor 720 is coupled to the transistor 715. The second terminal of the transistor 720 is coupled to the common terminal, which provides the common potential. The control terminal of the transistor 720 is coupled to the transistors 705, 725, 730, 735 and the second output of the delay comparator 425 (SIGN_{M}[0]).

The transistor 725 has a first terminal, a second terminal, and a control terminal. The first terminal of the transistor 725 is coupled to a supply terminal, which provides a supply voltage (e.g., V_{DD}, AVDD, etc.). The second terminal of the transistor 725 is coupled to the transistors 705, 720, 730, 735 and the second output of the delay comparator 425 (SIGN_{M}[0]). The control terminal of the transistor 725 is coupled to the transistor 705 and the voltage-controlled delay circuitry 610 (OUTP).

The transistor 730 has a first terminal, a second terminal, and a control terminal. The first terminal of the transistor 730 is coupled to the supply terminal, which provides the supply voltage. The second terminal of the transistor 730 is coupled to the transistors 705, 720, 725, 735 and the second output of the delay comparator 425 (SIGN_{M}[0]). The control terminal of the transistor 730 is coupled to the transistors 710, 715, 735, 740 and the first output of the delay comparator 425 (SIGN_{P}[0]).

The transistor 735 has a first terminal, a second terminal, and a control terminal. The first terminal of the transistor 735 is coupled to the supply terminal, which provides the supply voltage. The second terminal of the transistor 735 is coupled to the transistors 710, 715, 730, 740 and the first output of the delay comparator 425 (SIGN_{P}[0]). The control terminal of the transistor 735 is coupled to the transistors 705, 720, 725, 730 and the second output of the delay comparator 425 (SIGN_{M}[0]).

The transistor 740 has a first terminal, a second terminal, and a control terminal. The first terminal of the transistor 740 is coupled to the supply terminal, which provides the supply voltage. The second terminal of the transistor 740 is coupled to the transistors 710, 715, 730, 735 and the first output of the delay comparator 425 (SIGN_{P}[0]). The control terminal of the transistor 740 is coupled to the transistor 715 and the voltage-controlled delay circuitry 620 (OUTM).

The transistor 745 has a first terminal, a second terminal, and a control terminal. The first terminal of the transistor 745 is coupled to the supply terminal, which provides the supply voltage. The second terminal of the transistor 745 is coupled to the transistor 750. The control terminal of the transistor 745 is coupled to the second input of the voltage-controlled delay circuitry 610 (VC1_1).

The transistor 750 has a first terminal, a second terminal, and a control terminal. The first terminal of the transistor 750 is coupled to the transistor 745. The second terminal of the transistor 750 is coupled to the transistor 755 and the first input of the delay comparator 425 (INP). The control terminal of the transistor 750 is coupled to the transistor 755 and the input of the first input of the voltage-controlled delay circuitry 610 (DELAY₀).

The transistor 755 has a first terminal, a second terminal, and a control terminal. The first terminal of the transistor 755 is coupled to the transistor 750 and the first input of the delay comparator 425 (INP). The second terminal of the transistor 755 is coupled to the common terminal, which provides the common potential. The control terminal of the transistor 755 is coupled to the transistor 750 and the first input of the voltage-controlled delay circuitry 610 (DELAY₀).

The transistor 760 has a first terminal, a second terminal, and a control terminal. The first terminal of the transistor 760 is coupled to the supply terminal, which provides the supply voltage. The second terminal of the transistor 760 is coupled to the transistor 765. The control terminal of the transistor 760 is coupled to the second input of the voltage-controlled delay circuitry 620 (VC1_2).

The transistor 765 has a first terminal, a second terminal, and a control terminal. The first terminal of the transistor 765 is coupled to the transistor 760. The second terminal of the transistor 765 is coupled to the transistor 770 and the second input of the delay comparator 425 (INM). The control terminal of the transistor 765 is coupled to the transistor 770 and the first input of the voltage-controlled delay circuitry 620 (DELAY₁).

The transistor 770 has a first terminal, a second terminal, and a control terminal. The first terminal of the transistor 770 is coupled to the transistor 765 and the second input of the delay comparator 425 (INM). The second terminal of the transistor 770 is coupled to the common terminal, which provides the common potential. The control terminal of the transistor 770 is coupled to the transistor 765 and the first input of the voltage-controlled delay circuitry 620 (DELAY₁).

In the example of FIG. 7, the transistors 705, 710, 715, 720, 745, 750, 760, 765 are n-channel metal-oxide semiconductor field-effect transistors (MOSFETs). Alternatively, the transistors 705, 710, 715, 720, 745, 750, 760, 765 may be n-channel field-effect transistors (FETs), n-channel insulated-gate bipolar transistors (IGBTs), n-channel junction field effect transistors (JFETs), NPN bipolar junction transistors (BJTs) or, with slight modifications, p-type equivalent devices. In the example of FIG. 7, the transistors 725, 730, 735, 740, 755, 770 are p-channel MOSFETs. Alternatively, the transistors 725, 730, 735, 740, 755, 770 may be p-channel FETs, p-channel IGBTs, p-channel JFETs, PNP BJTs, or, with slight modifications, N-type equivalent devices. The transistors 705, 710, 715, 720, 725, 730, 735, 740, 745, 750, 755, 760, 765, 770 may be depletion mode devices, drain-extended devices, enhancement mode devices, natural transistors or other type of device structure transistors. Furthermore, the transistors 705, 710, 715, 720, 725, 730, 735, 740, 745, 750, 755, 760, 765, 770 may be implemented in/over a silicon substrate (Si), a silicon carbide substrate (SiC), a gallium nitride substrate (GaN) or a gallium arsenide substrate (GaAs).

In example operation, the transistor 745 regulates the supply of current to the transistor 750 responsive to a first control voltage (VC1_1) from the offset voltage control circuitry 240. The transistors 750, 755 delay the supply of the first delay signal (DELAY₀) to the transistors 705, 725 responsive to the transistor 745. Similarly, the transistor 760 regulates the supply of current to the transistor 765 responsive to a second control voltage (VC1_2) from the offset voltage control circuitry 240. The transistors 765, 770 delay the supply of the second delay signal (DELAY₁) to the transistors 715, 740 responsive to the transistor 760. Advantageously, the offset voltage control circuitry 240 may set the delay of the voltage-controlled delay circuitry 610, 620 responsive to the control voltages.

In such example operations, the transistors 705, 725 receive the first delay signal (Delay₀) and the transistors 715, 740 receive the second delay signal (Delay₁). In some examples, the transistors 705, 720, 730 set the sign output to a logical one responsive the transistor 705 conducting current prior to the transistor 715. In such examples, the first delay signal (Delay₀) has a rising edge prior to the second delay signal (Delay₁). In another example, the transistors 710, 715, 735 set the sign output to a logical zero responsive to the transistor 715 conducting current prior to the transistor 705. In such examples, the second delay signal (Delay₁) has a rising edge prior to the first delay signal (Delay₀). In some examples, the size of the transistor 705, 715 (e.g., channel length, channel width, etc.) are modified to bias the delay comparator 425. For example, increasing the size of the transistor 715 and decreasing the size of the transistor 705 produces the interpolated threshold voltage 555 of FIG. 5C. In other examples, the transistors 705, 715 are implemented using different transistor devices to produce an interpolated voltage threshold. In yet another example, the delay comparator 425 further includes a capacitor coupled to the control terminal of one of the transistors 705, 715. Such capacitor delays setting the control terminal of the one of the transistors 705, 715 to produce an interpolated voltage threshold. Advantageously, the delay comparator 425 sets the sign bit responsive to the timing of the delay signals. Further example operations of the delay comparator 425 and the voltage-controlled delay circuitry 610, 620 are further illustrated and described in connection with FIG. 9.

FIG. 8 is a schematic diagram of an example of the offset voltage control circuitry 240 of FIG. 2. The offset voltage control circuitry 240 of FIG. 8 includes example current source circuitry 805, a first example resistor ladder 810, a second example resistor ladder 815, a third example resistor ladder 820, a fourth example resistor ladder 825, a fifth example resistor ladder 830, a sixth example resistor ladder 835, a first example multiplexer 840, and a second example multiplexer 845. The resistor ladder 810 of FIG. 8 includes a first example resistor 850, a second example resistor 855, a third example resistor 860, a fourth example resistor 865, a fifth example resistor 870, a sixth example resistor 875, a seventh example resistor 880, an eighth example resistor 885, and a ninth example resistor 890.

The current source circuitry 805 has a first terminal and a second terminal. The first terminal of the current source circuitry 805 is coupled to the supply terminal, which provides the supply voltage. The second terminal of the current source circuitry 805 is coupled to the resistor ladder 810.

The resistor ladder 810 has a first terminal, a second terminal, and outputs. The first terminal of the resistor ladder 810 is coupled to the current source circuitry 805. The second terminal of the resistor ladder 810 is coupled to the resistor ladder 815. The outputs of the resistor ladder 810 are coupled to the multiplexers 840, 845.

The resistor ladder 815 has a first terminal, a second terminal, and outputs. The first terminal of the resistor ladder 815 is coupled to the resistor ladder 810. The second terminal of the resistor ladder 815 is coupled to the resistor ladder 820. The outputs of the resistor ladder 815 are coupled to the multiplexers 840, 845.

The resistor ladder 820 has a first terminal, a second terminal, and outputs. The first terminal of the resistor ladder 820 is coupled to the resistor ladder 815. The second terminal of the resistor ladder 820 is coupled to the resistor ladder 825. The outputs of the resistor ladder 820 are coupled to the multiplexers 840, 845.

The resistor ladder 825 has a first terminal, a second terminal, and outputs. The first terminal of the resistor ladder 825 is coupled to the resistor ladder 820. The second terminal of the resistor ladder 825 is coupled to the resistor ladder 830. The outputs of the resistor ladder 825 are coupled to the multiplexers 840, 845.

The resistor ladder 830 has a first terminal, a second terminal, and outputs. The first terminal of the resistor ladder 830 is coupled to the resistor ladder 825. The second terminal of the resistor ladder 830 is coupled to the resistor ladder 835. The outputs of the resistor ladder 830 are coupled to the multiplexers 840, 845.

The resistor ladder 835 has a first terminal, a second terminal, and a third terminal. The first terminal of the resistor ladder 835 is coupled to the resistor ladder 830. The second and third terminals of the resistor ladder 835 are coupled to the common terminal, which provides the common potential.

The multiplexer 840 has inputs, a control input, and outputs. The inputs of the multiplexer 840 are coupled to the resistor ladders 810, 815, 820, 825, 830. The control input of the multiplexer 840 receives a first multiplexer select signal (MUX_SEL₀[0:7]). The outputs of the multiplexer 840 are structured to be coupled to the voltage-controlled delay circuitry 610.

The multiplexer 845 has inputs, a control input, and outputs. The inputs of the multiplexer 845 are coupled to the resistor ladders 810, 815, 820, 825, 830. The control input of the multiplexer 845 receives a second multiplexer select signal (MUX_SEL₁[0:7]). The outputs of the multiplexer 845 are structured to be coupled to the voltage-controlled delay circuitry 620.

The resistor 850 has a first terminal and a second terminal. The first terminal of the resistor 850 is coupled to the current source circuitry 805 and the resistor 890. The second terminal of the resistor 850 is coupled to the multiplexers 840, 845 and the resistor 855.

The resistor 855 has a first terminal and a second terminal. The first terminal of the resistor 855 is coupled to the multiplexers 840, 845 and the resistor 850. The second terminal of the resistor 855 is coupled to the multiplexers 840, 845 and the resistor 860.

The resistor 860 has a first terminal and a second terminal. The first terminal of the resistor 860 is coupled to the multiplexers 840, 845 and the resistor 855. The second terminal of the resistor 860 is coupled to the multiplexers 840, 845 and the resistor 865.

The resistor 865 has a first terminal and a second terminal. The first terminal of the resistor 865 is coupled to the multiplexers 840, 845 and the resistor 860. The second terminal of the resistor 865 is coupled to the multiplexers 840, 845 and the resistor 870.

The resistor 870 has a first terminal and a second terminal. The first terminal of the resistor 870 is coupled to the multiplexers 840, 845 and the resistor 865. The second terminal of the resistor 870 is coupled to the multiplexers 840, 845 and the resistor 875.

The resistor 875 has a first terminal and a second terminal. The first terminal of the resistor 875 is coupled to the multiplexers 840, 845 and the resistor 870. The second terminal of the resistor 875 is coupled to the multiplexers 840, 845 and the resistor 880.

The resistor 880 has a first terminal and a second terminal. The first terminal of the resistor 880 is coupled to the multiplexers 840, 845 and the resistor 875. The second terminal of the resistor 880 is coupled to the multiplexers 840, 845 and the resistor 885.

The resistor 885 has a first terminal and a second terminal. The first terminal of the resistor 885 is coupled to the multiplexers 840, 845 and the resistor 880. The second terminal of the resistor 885 is coupled to the resistor ladder 815 and the resistor 890.

The resistor 890 has a first terminal and a second terminal. The first terminal of the resistor 890 is coupled to the current source circuitry 805 and the resistor 850. The second terminal of the resistor 890 is coupled to the resistor ladder 815.

In example operations, the resistor ladders 810, 815, 820, 825, 830, 835 provide a series of possible control voltages responsive to the current from the current source circuitry 805. The multiplexers 840, 845 are structured to provide one of the possible control voltages to one of the voltage-controlled delay circuitry 610, 620, 630, 640, 650, 660 responsive to the multiplexer select signals. In some examples, the offset voltage control circuitry 240 includes a multiplexer for each of the voltage-controlled delay circuitry 610, 620, 630, 640, 650, 660. Advantageously, the multiplexers 840, 845 may supply a wide range of possible control voltages to the voltage-controlled delay circuitry 610, 620, 630, 640, 650, 660. Advantageously, the delays of the voltage-controlled delay circuitry 610, 620, 630, 640, 650, 660 are programmable by the multiplexer select signals (MUX_SEL₀[0:7], MUX_SEL₁[0:7]). Further example operations of the offset voltage control circuitry 240 are further illustrated and described in connection with FIG. 9.

FIG. 9 is a flowchart representative of example machine-readable instructions or example operations that may be at least one of executed, instantiated, or performed using example implementations of the reference generation circuitry of FIGS. 2 and 3, the voltage comparator stage of FIGS. 2, 4, and 6, the delay comparator stage of FIGS. 2, 4, and 6, and the offset voltage control circuitry of FIG. 8, or more generally the FADC of FIGS. 1 and 2.

The example operations 900 of FIG. 9 begin at Block 905 at which the voltage comparator stage 220 of FIGS. 2, 4, and 6 receives an analog input voltage. In example operations, the voltage comparator stage 220 receives an analog input signal (ANALOG_{IN}) from an analog source. In some examples, such as FIGS. 2, 4, and 6, the voltage comparator stage receives plus and minus input signals (ANALOG_{IN_P}, ANALOG_{IN_M}), which are a pair of differential signals. In such example operations, the voltage comparators 405, 410, 415, 420 of FIGS. 4 and 6 receive the analog input signal. In some examples, the voltage comparator stage 220 includes additional instances of the voltage comparators 405, 410, 415, 420. In such examples, the number of instances of the voltage comparators 405, 410, 415, 420 corresponds to the resolution of the FADC 160. For example, the voltage comparator stage 220 includes ten of the voltage comparators 405, 410, 415, 420 responsive to the FADC 160 having a five bit resolution.

The reference generation circuitry 210 of FIGS. 2 and 3 generates reference voltages. (Block 910). In example operations, the resistors 306, 309, 312, 315, 318, 321, 324, 327, 330 of FIG. 3 generate plus reference voltages (V_{REF_P}[0:9]) responsive to current from the current source circuitry 303 of FIG. 3. Similarly, the resistors 339, 342, 345, 348, 351, 354, 357, 360, 363 of FIG. 3 generate minus reference voltages (V_{REF_M}[0:9]) responsive to current from the current source circuitry 336 of FIG. 3. In such example operations, the plus and minus reference voltages (V_{REF_P}[0:9], V_{REF_M}[0:9]) differentially represent reference voltages (V_{REF}[0:9]). For example, the voltage difference between the second terminal of the resistor 330 and the first terminal of the resistor 339 form the first reference voltage (V_{REF}[0]). The resistors 306, 309, 312, 315, 318, 321, 324, 327, 330, 339, 342, 345, 348, 351, 354, 357, 360, 363 provide the reference voltages (V_{REF_P}[0:9], V_{REF_M}[0:9]) to the voltage comparator stage 220. Advantageously, the resistors 306, 309, 312, 315, 318, 321, 324, 327, 330, 339, 342, 345, 348, 351, 354, 357, 360, 363 produce a plurality of different reference voltages, such as the voltage thresholds 545, 550 of FIG. 5C. Advantageously, changing the magnitudes of the current source circuitry 303, 336 adjusts the reference voltages.

In some examples, the offset circuitry 369 of FIG. 3 adjusts the common mode voltage of the differential reference voltages. For example, closing the switches 375, 384 of FIG. 3 increases the common mode voltage of the reference voltages responsive to currents of the current source circuitry 372, 387 of FIG. 3. In another example, closing the switches 378, 381 of FIG. 3 decreases the common mode voltage of the reference voltages responsive to currents of the current source circuitry 372, 387. Advantageously, changing the magnitudes of the current source circuitry 372, 387 adjusts the common mode voltage of the differential reference voltages. Advantageously, the offset circuitry 369 may reduce noise and improve linear performance of the FADC 160 by adjusting the refence voltages.

The voltage comparator stage 220 compares the analog input voltage to the reference voltages. (Block 915). In example operations, the voltage comparators 405, 410, 415, 420 compare the analog input signal (ANALOG_{IN}) to a respective one of the reference voltages (V_{REF}[0:N]). For example, the voltage comparator 405 compares a first reference voltage (V_{REF}[0]) to the analog input signal (ANALOG_{IN}) and the voltage comparator 410 compares a second reference voltage (V_{REF}[1]) to the analog input signal (ANALOG_{IN}). As described above, the voltage comparator stage 220 may include a number of additional ones of the voltage comparators 405, 410, 415, 420 responsive to the resolution of the FADC 160.

The voltage comparator stage 220 generates sign bits based on the comparison of the input voltage to the reference voltages. (Block 920). In example operations, the voltage comparators 405, 410, 415, 420 generate a sign bit responsive to a comparison of the analog input signal (ANALOG_{IN}) to the respective ones of the reference voltages. For example, the voltage comparator 405 produces a first sign bit (SIGN[0]) based on the comparison of the analog input signal (ANALOG_{IN}) to a first one of the reference voltages. In such an example, the voltage comparator 405 sets the first sign bit to a logical one (e.g., a logic high) responsive to the analog input voltage being greater than the first one of the reference voltages. Also, the voltage comparator 405 sets the first sign bit to a logical zero (e.g., a logic low) responsive to the analog input voltage being less than the first one of the reference voltages. Similarly, the voltage comparators 410, 415, 420 produce additional sign bits responsive to the comparison of respective ones of the reference voltages to the analog input signal (ANALOG_{IN}).

The voltage comparator stage 220 generates delay outputs based on the difference between the analog input voltage and the reference voltages. (Block 925). In example operations, the voltage comparators 405, 410, 415, 420 produce a second output pulse, which is set to a logical one (e.g., a logic high) responsive to the relation of the proximity of the reference voltage to the analog input signal (ANALOG_{IN}). As illustrated by the plot 525 of FIG. 5B, the duration of the time in which the rising edge of the delay output, illustrated by the timing diagram 500 of FIG. 5A, increases as the analog input signal (ANALOG_{IN}) approaches the respective one of the reference voltage. Advantageously, the timing of the rising edge of the delay output of the voltage comparators 405, 410, 415, 420 represent the proximity of the analog input voltage to the reference voltage. Advantageously, delay increases as the reference voltage approaches the analog input signal (ANALOG_{IN}).

The delay comparator stage 230 of FIGS. 2, 4, and 6 interpolates thresholds between reference voltages. (Block 930). In example operations, the delay comparators 425, 430, 435, 440, 445, 450 of FIGS. 4 and 6 receive respective pairs of subsequent delay outputs from the voltage comparators 405, 410, 415, 420. For example, the delay comparators 425, 430, 435, receive the first delay output (DELAY₀) from the voltage comparator 405 and a second delay output (DELAY₁) from the voltage comparator 410. In such an example, the delay comparators 425, 430, 435 interpolate the thresholds 555, 560, 565 of FIG. 5C responsive to the voltage comparators 405, 410 comparing the voltage thresholds 545, 550 to the analog input signal (ANALOG_{IN}). In such example operations, the thresholds 555, 560, 565 are set by the sizing of the transistors 705, 715 of FIG. 7. For example, the delay comparator 430 corresponds to the threshold 560 responsive to the transistors 705, 715 being of the same size. In such an example, the size of the transistors 705, 715 correspond to at least one of the channel length or width. In another example, the delay comparator 425 corresponds to the threshold 555 responsive the size of the transistor 715 being greater than the size of the transistor 705. In such an example, the threshold voltage of the transistor 715 is greater than the threshold voltage of the transistor 705 responsive to a difference in at least one of the channel width or length. In yet another example, the delay comparator 435 corresponds to the threshold 565 responsive to the size of the transistor 705 being greater than the size of the transistor 715. In such an example, the threshold voltage of the transistor 705 is greater than the threshold voltage of the transistor 715 responsive to a difference in at least one of channel width or length.

Similarly, the delay comparators 440, 445, 450 receive a third delay output (DELAY_{N-1}) from the voltage comparator 415 and a fourth delay output (DELAY_{N}) from the voltage comparator 420. Advantageously, changing the sizing of the transistors 705, 715 in the respective ones of the delay comparators 425, 430, 435 adjusts the thresholds 555, 560, 565. In some examples, the number of delay comparators may be modified to interpolate a different number of thresholds between two reference voltages. For example, the delay comparator stage 230 may interpolate the threshold 560 using the delay comparator 430.

In some examples, as illustrated by the dashed outline, the offset voltage control circuitry 240 of FIGS. 2 and 8 generates delay offset correction voltages. (Block 935). In some examples, such as in FIG. 6, the delay comparator stage 230 includes the voltage-controlled delay circuitry 610, 620, 630, 640, 650 of FIG. 6. In such examples, the FADC 160 includes the offset voltage control circuitry 240 to generate delay offset correction voltages. In example operations, the resistor ladders 810, 815, 820, 825, 830 of FIG. 8 produce a range of possible offset control voltages responsive to the current from the current source circuitry 805 of FIG. 8 through the resistors 850, 855, 860, 865, 870, 875, 880, 885 of FIG. 8. In such example operations, the resistor 890 of FIG. 8 reduces the on-chip size of the resistors 850, 855, 860, 865, 870, 875, 880, 885 responsive to reducing the length of the polysilicon in favor of increasing the width of the polysilicon. Advantageously, structuring the resistors ladders 810, 815, 820, 825, 830 using the structure of the resistors 850, 855, 860, 865, 870, 875, 880, 885, 890 reduces the system on chip (SoC) size of the offset voltage control circuitry 240.

In such example operations, the multiplexers 840, 845 supply one of the possible offset control voltages of the resistor ladders 810, 815, 820, 825, 830 responsive to multiplexer select signals (MUX_SEL[0:7]). Although in the example of FIG. 8, the offset voltage control circuitry 240 includes the multiplexer 840, 845, in other examples, the offset voltage control circuitry 240 includes a multiplexer for one or more of the voltage-controlled delay circuitry 610, 620, 630, 640, 650. In such examples, the multiplexers 840, 845 may provide a different voltage of the resistor ladders 810, 815, 820, 825, 830 to the voltage-controlled delay circuitry 610, 620, 630, 640, 650. Advantageously, the offset voltage control circuitry 240 allows the voltage-controlled delay circuitry 610, 620, 630, 640, 650 to have different delays.

In some examples, as illustrated by the dashed outline, the delay comparator stage 230 delays the delay outputs based on the offset correction voltages. (Block 940). In example operations, manufacturing variations (e.g., inaccuracies, tolerances, etc.) create non-ideal sizing of the transistors 705, 715 in the respective ones of the delay comparators 425, 430, 435. The non-ideal sizing of the transistors 705, 715 modify the thresholds 555, 560, 565 responsive to changes in the sizing of the transistor 705 in relation to the transistor 715 and vice versa. In example operations, the voltage-controlled delay circuitry 610, 620, 630, 640, 650 delay the supply of the delay outputs from the voltage comparators 405, 410, 415, 420 responsive to control voltages from the offset voltage control circuitry 240 of FIGS. 2 and 8. For example, the transistors 745, 760 of FIG. 7 control the rate at which the transistors 750, 755, 765, 770 of FIG. 7 set the inputs of the delay comparator 425. In such an example, adjusting the supply of current by the transistors 745, 760 of FIG. 7 controls the switching of the transistors 750, 755, 765, 770.

The delay comparator stage 230 compares delay outputs to the interpolated thresholds. (Block 945). In example operations, the delay comparators 425, 430, 435, 440, 445, 450 generate sign bits responsive to which one of the respective instances of the transistors 705, 710 begin to conduct current first. For example, the delay comparator 425 sets the sign bit to a logical one responsive to the transistor 705 to conducting current prior to the transistor 715. Such an example occurs responsive to the delay output of the voltage comparator 405 generating a delay output having a rising edge prior to a rising edge of the delay output of the voltage comparator 410. In another example, the delay comparator 425 sets the sign bit to a logical zero responsive to the transistor 715 conducting current prior to the transistor 705. Such an example occurs responsive to the delay output of the voltage comparator 410 generating a delay output having a rising edge prior to a rising edge of the delay output of the voltage comparator 405. Advantageously, the delay comparators 425, 430, 435, 440, 445, 450 produce sign bits responsive to the delay outputs of the voltage comparators 405, 410, 415, 420.

The delay comparator stage 230 generates remaining sign bits based on the comparison of the delay outputs to the three interpolated thresholds. (Block 950). In example operations, the first received edge of the delay output sets the output of the delay comparators 425, 430, 435, 440, 445, 450. For example, the rising edge of the first delay signal 505 (Delay₀) at the time 515 sets the sign output of the delay comparator 425 (SIGN[10]). In some such examples, the voltage-controlled delay circuitry 610 sets the sign output of the delay comparator 425 to a logic one responsive providing a rising edge prior to the voltage-controlled delay circuitry 620. Alternatively, the voltage-controlled delay circuitry 620 sets the sign output of the delay comparator 425 to a logic zero responsive providing a rising edge prior to the voltage-controlled delay circuitry 610. In such examples, the delay comparator 425 latches the sign output until both inputs are logic zeros. In such example operations, the delay comparators 425, 430 produce a logic one sign bit and the delay comparator 435 produces a logic zero sign bit responsive to the analog input signal being between the interpolated thresholds 560, 565.

In example operations, as the voltage of the analog input approaches a reference voltage (V_{REF}) the delay output of the corresponding voltage comparator increases. Such example timing is illustrated and described in connection with FIG. 5B. In such example operations, although the timing of the voltage comparators increases, the increase in generation of the delay edge decreases the time the delay comparators need to produce the sign output. For example, if the analog input is approaching the first reference voltage (V_{ERF}[0]), the voltage comparator 405 has a relatively large delay on an edge of the delay output and the voltage comparator 405 has a smaller delay on the edge of the delay output. The difference in delays between the edges of the delay outputs of the voltage comparators 405, 410 rapidly set the sign bits of the delay comparators 425, 430, 435. In such examples, the voltage comparator 405 may take fifteen microseconds to produce the delay output and the delay comparators 425, 430, 435 will already be in the process of deciding the sign output responsive to the decreased delay of the delay output of the voltage comparator 410.

Advantageously, using the delay comparator stage 230 to interpolate voltages decreases the time needed to determine the sign bits in comparison to existing two voltage comparator stages. For example, in designs that utilize two cascaded voltage comparator stages, the second voltage comparator stage must wait to produce sign bits until after the first voltage comparator stage is complete. Advantageously, the delay comparator stage 230 reduces the time of the second cascaded comparison stage responsive to using the first received rising edge to produce the sign output. For example, the delay comparator 425 sets the sign output (SIGN[10]) responsive to the rising edge of the first delay signal 505 (Delay₀) at the time 515. Advantageously, the delay comparator 425 produces the sign output regardless of the timing of the rising edge of the second delay signal 510 (Delay₁) at the time 520. Such a reduction in timing increases a conversion speed of the FADC 160.

Advantageously, the analog input signal (ANALOG_{IN}) corresponds to a voltage between one of the voltages 545, 550, 555, 560, 565 responsive to a change in logic of the sign output. For example, the analog input signal (ANALOG_{IN}) has a voltage between the thresholds 560, 565 responsive to the delay comparator 430 producing a sign output having a logical one state and the delay comparator 435 producing a sign output having a logical zero state. Advantageously, the delay comparators 425, 430, 435, 440, 445, 450 interpolate sign outputs between the voltage thresholds 545, 550.

The FADC 160 represents a digital output of the analog input voltage using the sign bits. (Block 955). In example operations, the FADC 160 has a resolution set by the number of voltage thresholds and interpolated thresholds of the voltage comparator stage 220 and the delay comparator stage 230. For example, the FADC 160 has a five-bit resolution responsive to the voltage comparator stage 220 having ten voltage comparators and the delay comparator stage 230 having twenty-four delay comparators. In such an example, the two additional voltage comparators of the voltage comparator stage 220 represent a maximum and minimum voltage of the FADC 160. In such example operations, the alignment and correction circuitry 140 receives the sign outputs of the voltage comparator stage 220 and the delay comparator stage 230. The alignment and correction circuitry 140 converts the number of sign outputs set to a logical one to a digital value. In such an example, the transition from sign outputs set to a logical one to sign bits set to a logical zero corresponds to the digital value. Advantageously, the digital value of the alignment and correction circuitry 140 represents the analog value of the analog input signal (ANALOG_{IN}). Control proceeds to return to Block 905.

Example methods are described with reference to the flowchart illustrated in FIG. 9. However, many other methods of implementing the FADC 160 of FIGS. 1 and 2 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

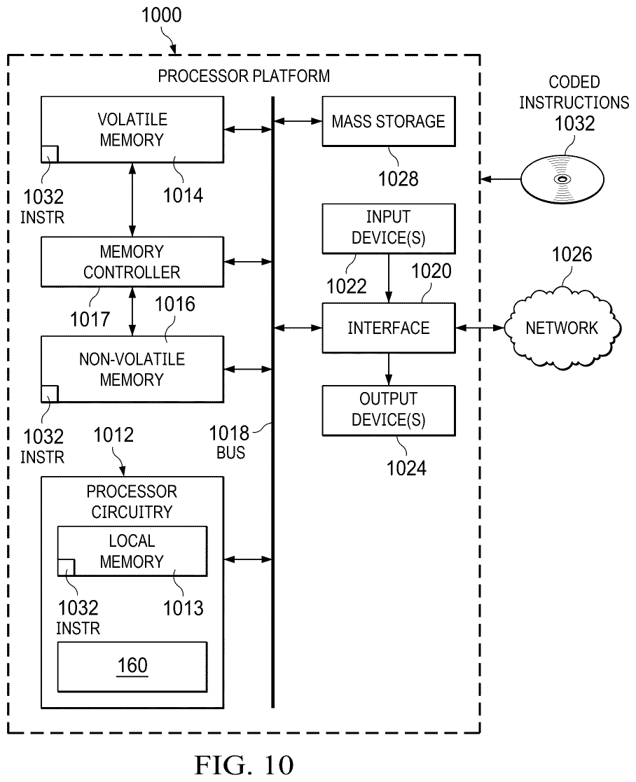

FIG. 10 is a block diagram of an example programmable circuitry platform 1000 structured to one or a combination of execute or instantiate one or more of the example machine-readable instructions or the example operations of FIG. 9 to implement the FADC 160 of FIG. 2. The programmable circuitry platform 1000 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing or electronic device.

The programmable circuitry platform 1000 of the illustrated example includes programmable circuitry 1012. The programmable circuitry 1012 of the illustrated example is hardware. For example, the programmable circuitry 1012 can be implemented by one or more integrated circuits, logic circuits, FPGAs, microprocessors, CPUs, GPUs, DSPs, or microcontrollers from any desired family or manufacturer. The programmable circuitry 1012 may be implemented by one or more semiconductor based (e.g., silicon based) devices. In this example, the programmable circuitry 1012 implements the FADC 160. In another example, a block in programmable circuitry platform 1000 engaged in conversion of an analog signal to a digital signal implements FADC 160. In yet another example, a block in programmable circuitry platform 1000 engaged in conversion of an analog signal to a digital signal execute some or all of the machine-readable instructions of the flowchart of FIG. 9

The programmable circuitry 1012 of the illustrated example includes a local memory 1013 (e.g., a cache, registers, etc.). The programmable circuitry 1012 of the illustrated example is in communication with main memory 1014, 1016, which includes a volatile memory 1014 and a non-volatile memory 1016, by a bus 1018. The volatile memory 1014 may be implemented by one or more Synchronous Dynamic Random Access Memory (SDRAM), Dynamic Random Access Memory (DRAM), RAMBUS® Dynamic Random Access Memory (RDRAM®), or any other type of RAM device. The non-volatile memory 1016 may be implemented by one or a combination of flash memory or any other desired type of memory device. Access to the main memory 1014, 1016 of the illustrated example is controlled by a memory controller 1017. In some examples, the memory controller 1017 may be implemented by one or more integrated circuits, logic circuits, microcontrollers from any desired family or manufacturer, or any other type of circuitry to manage the flow of data going to and from the main memory 1014, 1016.

The programmable circuitry platform 1000 of the illustrated example also includes interface circuitry 1020. The interface circuitry 1020 may be implemented by hardware in according to any type of interface standard, such as an Ethernet interface, a universal serial bus (USB) interface, a Bluetooth® interface, a near field communication (NFC) interface, a Peripheral Component Interconnect (PCI) interface, or a Peripheral Component Interconnect Express (PCIe) interface.

In the illustrated example, one or more input devices 1022 are connected to the interface circuitry 1020. The input device(s) 1022 permit(s) a user (e.g., a human user, a machine user, etc.) to enter one of or a combination of data or commands into the programmable circuitry 1012. The input device(s) 1022 can be implemented by, for example, one of or a combination of an audio sensor, a microphone, a camera (still or video), a keyboard, a button, a mouse, a touchscreen, a trackpad, a trackball, an isopoint device, or a voice recognition system.

One or more output devices 1024 are also connected to the interface circuitry 1020 of the illustrated example. The output device(s) 1024 can be implemented, for example, by one of or a combination of display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, or speaker. The interface circuitry 1020 of the illustrated example, thus, includes one of or a combination of a graphics driver card, a graphics driver chip, or graphics processor circuitry such as a GPU.

The interface circuitry 1020 of the illustrated example also includes a communication device such as one of or a combination of a transmitter, a receiver, a transceiver, a modem, a residential gateway, a wireless access point, or a network interface to facilitate exchange of data with external machines (e.g., computing devices of any kind) by a network 1026. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 1000 of the illustrated example also includes one or more mass storage discs or devices 1028 to store one or more of firmware, software, or data. Examples of such mass storage discs or devices 1028 include one or more magnetic storage devices (e.g., floppy disk, drives, HDDs, etc.), optical storage devices (e.g., Blu-ray disks, CDs, DVDs, etc.), RAID systems, or solid-state storage discs or devices such as flash memory devices and SSDs.

The machine-readable instructions 1032, which may be implemented by the machine-readable instructions of FIG. 9, may be stored in one of or a combination of the mass storage device 1028, in the volatile memory 1014, in the non-volatile memory 1016, or on at least one non-transitory computer readable storage medium such as a CD or DVD which may be removable.

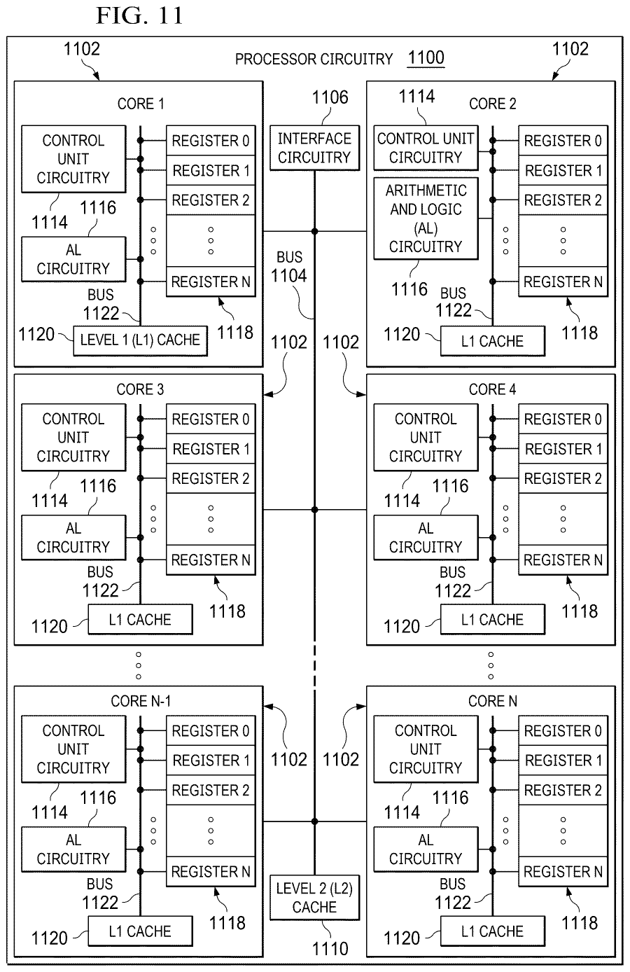

FIG. 11 is a block diagram of an example implementation of the programmable circuitry 1012 of FIG. 10. In this example, the programmable circuitry 1012 of FIG. 10 is implemented by a microprocessor 1100. For example, the microprocessor 1100 may be a general-purpose microprocessor (e.g., general-purpose microprocessor circuitry). The microprocessor 1100 executes some or all of the machine-readable instructions of the flowchart of FIG. 9 to effectively instantiate the circuitry of FIG. 2 as logic circuits to perform operations corresponding to those machine-readable instructions. In some such examples, the circuitry of FIG. 2 is instantiated by the hardware circuits of the microprocessor 1100 in combination with the machine-readable instructions. For example, the microprocessor 1100 may be implemented by multi-core hardware circuitry such as a CPU, a DSP, a GPU, an XPU, etc. Although it may include any number of example cores 1102 (e.g., 1 core), the microprocessor 1100 of this example is a multi-core semiconductor device including N cores. The cores 1102 of the microprocessor 1100 may operate independently or may cooperate to execute machine-readable instructions. For example, machine code corresponding to a firmware program, an embedded software program, or a software program may be executed by one of the cores 1102 or may be executed by multiple ones of the cores 1102 at the same or different times. In some examples, the machine code corresponding to the firmware program, the embedded software program, or the software program is split into threads and executed in parallel by two or more of the cores 1102. The software program may correspond to a portion or all of the machine-readable instructions or operations represented by the flowchart of FIG. 9.

The cores 1102 may communicate by a first example bus 1104. In some examples, the first bus 1104 may be implemented by a communication bus to effectuate communication associated with one(s) of the cores 1102. For example, the first bus 1104 may be implemented by at least one of an Inter-Integrated Circuit (I2C) bus, a Serial Peripheral Interface (SPI) bus, a PCI bus, or a PCIe bus. Also or alternatively, the first bus 1104 may be implemented by any other type of computing or electrical bus. The cores 1102 may obtain data, instructions, and signals from one or more external devices by example interface circuitry 1106. The cores 1102 may output data, instructions, and signals to the one or more external devices by the interface circuitry 1106. Although the cores 1102 of this example include example local memory 1120 (e.g., Level 1 (L1) cache that may be split into an L1 data cache and an L1 instruction cache), the microprocessor 1100 also includes example shared memory 1110 that may be shared by the cores (e.g., Level 2 (L2 cache)) for high-speed access to data and instructions. Data and instructions may be transferred (e.g., shared) by one of or a combination of writing to or reading from the shared memory 1110. The local memory 1120 of each of the cores 1102 and the shared memory 1110 may be part of a hierarchy of storage devices including multiple levels of cache memory and the main memory (e.g., the main memory 1014, 1016 of FIG. 10). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 1102 may be referred to as a CPU, DSP, GPU, etc., or any other type of hardware circuitry. Each core 1102 includes control unit circuitry 1114, arithmetic and logic (AL) circuitry (sometimes referred to as an ALU) 1116, a plurality of registers 1118, the local memory 1120, and a second example bus 1122. Other structures may be present. For example, each core 1102 may include vector unit circuitry, single instruction multiple data (SIMD) unit circuitry, load/store unit (LSU) circuitry, branch/jump unit circuitry, floating-point unit (FPU) circuitry, etc. The control unit circuitry 1114 includes semiconductor-based circuits structured to control (e.g., coordinate) data movement within the corresponding core 1102. The AL circuitry 1116 includes semiconductor-based circuits structured to perform one or more mathematic or logic operations on the data within the corresponding core 1102. The AL circuitry 1116 of some examples performs integer based operations. In other examples, the AL circuitry 1116 also performs floating-point operations. In yet other examples, the AL circuitry 1116 may include first AL circuitry that performs integer-based operations and second AL circuitry that performs floating-point operations. In some examples, the AL circuitry 1116 may be referred to as an Arithmetic Logic Unit (ALU).

The registers 1118 are semiconductor-based structures to store data and instructions such as results of one or more of the operations performed by the AL circuitry 1116 of the corresponding core 1102. For example, the registers 1118 may include vector register(s), SIMD register(s), general-purpose register(s), flag register(s), segment register(s), machine-specific register(s), instruction pointer register(s), control register(s), debug register(s), memory management register(s), machine check register(s), etc. The registers 1118 may be arranged in a bank as shown in FIG. 11. Alternatively, the registers 1118 may be organized in any other arrangement, format, or structure, such as by being distributed throughout the core 1102 to shorten access time. The second bus 1122 may be implemented by at least one of an I2C bus, a SPI bus, a PCI bus, or a PCIe bus.

Each core 1102 or, more generally, the microprocessor 1100 may include additional or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) or other circuitry may be present. The microprocessor 1100 is a semiconductor device fabricated to include many transistors interconnected to implement the structures described above in one or more integrated circuits (ICs) contained in one or more packages.

The microprocessor 1100 may include or cooperate with one or more accelerators (e.g., acceleration circuitry, hardware accelerators, etc.). In some examples, accelerators are implemented by logic circuitry to perform certain tasks more quickly and efficiently than can be done by a general-purpose processor. Examples of accelerators include ASICs and FPGAs such as those discussed herein. A GPU, DSP, or other programmable device can also be an accelerator. Accelerators may be on-board the microprocessor 1100, in the same chip package as the microprocessor 1100, or in one or more separate packages from the microprocessor 1100.

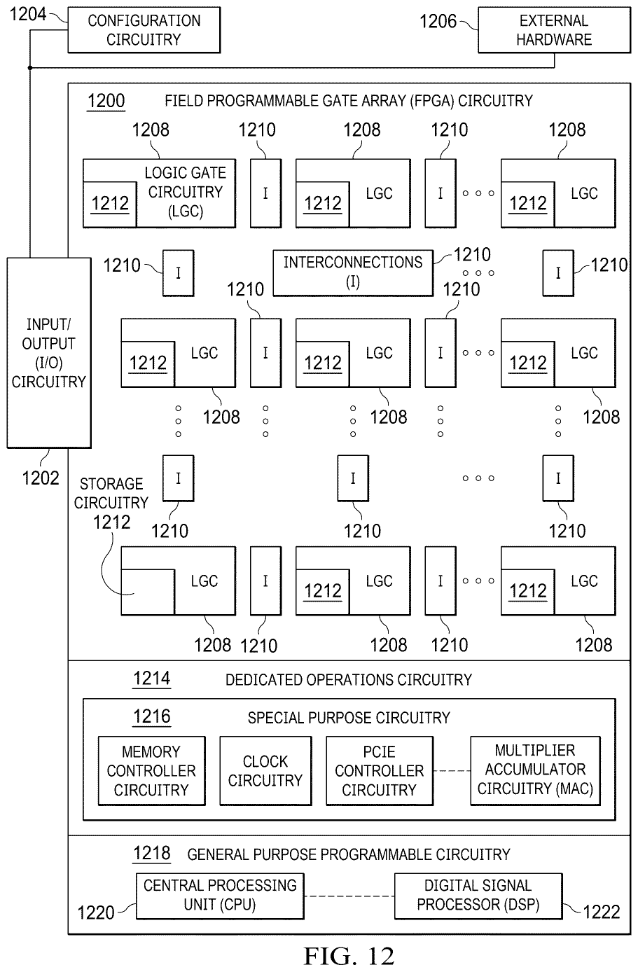

FIG. 12 is a block diagram of another example implementation of the programmable circuitry 1012 of FIG. 10. In this example, the programmable circuitry 1012 is implemented by FPGA circuitry 1200. For example, the FPGA circuitry 1200 may be implemented by an FPGA. The FPGA circuitry 1200 can be used, for example, to perform operations that could otherwise be performed by the example microprocessor 1100 of FIG. 11 executing corresponding machine-readable instructions. However, once configured, the FPGA circuitry 1200 instantiates the operations and functions corresponding to the machine-readable instructions in hardware and, thus, can often execute the operations/functions faster than they could be performed by a general-purpose microprocessor executing the corresponding software.

More specifically, in contrast to the microprocessor 1100 of FIG. 11 described above (which is a general purpose device that may be programmed to execute some or all of the machine-readable instructions represented by the flowchart(s) of FIG. 9 but whose interconnections and logic circuitry are fixed once fabricated), the FPGA circuitry 1200 of the example of FIG. 12 includes interconnections and logic circuitry that may be one of or a combination of configured, structured, programmed, and interconnected in different ways after fabrication to instantiate, for example, some or all of the operations/functions corresponding to the machine-readable instructions represented by the flowchart(s) of FIG. 9. In particular, the FPGA circuitry 1200 may be thought of as an array of logic gates, interconnections, and switches. The switches can be programmed to change how the logic gates are interconnected by the interconnections, effectively forming one or more dedicated logic circuits (unless and until the FPGA circuitry 1200 is reprogrammed). The configured logic circuits enable the logic gates to cooperate in different ways to perform different operations on data received by input circuitry. Those operations may correspond to some or all of the instructions (e.g., the software and/or firmware) represented by the flowchart(s) of FIG. 9. As such, the FPGA circuitry 1200 may be at least one of configured or structured to effectively instantiate some or all of the operations/functions corresponding to the machine-readable instructions of the flowchart(s) of FIG. 9 as dedicated logic circuits to perform the operations/functions corresponding to those software instructions in a dedicated manner analogous to an ASIC. Therefore, the FPGA circuitry 1200 may perform the operations/functions corresponding to the some or all of the machine-readable instructions of FIG. 9 faster than the general-purpose microprocessor can execute the same.

In the example of FIG. 12, the FPGA circuitry 1200 is at least one of configured or structured in response to being programmed (and/or reprogrammed one or more times) based on a binary file. In some examples, the binary file may be one of or both of compiled or generated based on instructions in a hardware description language (HDL) such as Lucid, Very High Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 1200 of FIG. 12 may at least one of access or load the binary file to cause the FPGA circuitry 1200 of FIG. 12 to be at least one of configured or structured to perform the one or more operations/functions. For example, the binary file may be implemented by one of or a combination of a bit stream (e.g., one or more computer-readable bits, one or more machine-readable bits, etc.), data (e.g., computer-readable data, machine-readable data, etc.), or machine-readable instructions accessible to the FPGA circuitry 1200 of FIG. 12 to at least one of configure or structure the FPGA circuitry 1200 of FIG. 12, or portion(s) thereof.

In some examples, the binary file is at least one of compiled, generated, transformed, or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is at least one of compiled, generated, or otherwise output from the uniform software platform based on the second instructions. In some examples, the FPGA circuitry 1200 of FIG. 12 may at least one of access or load the binary file to cause the FPGA circuitry 1200 of FIG. 12 to be at least one of configured or structured to perform the one or more operations/functions. For example, the binary file may be implemented by one of or a combination of a bit stream (e.g., one or more computer-readable bits, one or more machine-readable bits, etc.), data (e.g., computer-readable data, machine-readable data, etc.), or machine-readable instructions accessible to the FPGA circuitry 1200 of FIG. 12 to at least one of configure or structure the FPGA circuitry 1200 of FIG. 12, or portion(s) thereof.

The FPGA circuitry 1200 of FIG. 12, includes example input/output (I/O) circuitry 1202 to at least one of obtain or output data to/from at least one of example configuration circuitry 1204 or external hardware 1206. For example, the configuration circuitry 1204 may be implemented by interface circuitry that may obtain a binary file, which may be implemented by one or more of a bit stream, data, or machine-readable instructions, to configure the FPGA circuitry 1200, or portion(s) thereof. In some such examples, the configuration circuitry 1204 may obtain the binary file from one of or a combination of a user, a machine (e.g., hardware circuitry (e.g., programmable or dedicated circuitry) that may implement an Artificial Intelligence/Machine Learning (AI/ML) model to generate the binary file, etc.), or any combination(s) thereof). In some examples, the external hardware 1206 may be implemented by external hardware circuitry. For example, the external hardware 1206 may be implemented by the microprocessor 1100 of FIG. 11.

The FPGA circuitry 1200 also includes an array of example logic gate circuitry 1208, a plurality of example configurable interconnections 1210, and example storage circuitry 1212. The logic gate circuitry 1208 and the configurable interconnections 1210 are configurable to instantiate one or more operations/functions that may correspond to at least some of the machine-readable instructions of FIG. 9 and/or other desired operations. The logic gate circuitry 1208 shown in FIG. 12 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 1208 to enable configuration of one of or a combination of the electrical structures or the logic gates to form circuits to perform desired operations/functions. The logic gate circuitry 1208 may include other electrical structures such as look-up tables (LUTs), registers (e.g., flip-flops or latches), multiplexers, etc.

The configurable interconnections 1210 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 1208 to program desired logic circuits.

The storage circuitry 1212 of the illustrated example is structured to store result(s) of the one or more of the operations performed by corresponding logic gates. The storage circuitry 1212 may be implemented by registers or the like. In the illustrated example, the storage circuitry 1212 is distributed amongst the logic gate circuitry 1208 to facilitate access and increase execution speed.

The example FPGA circuitry 1200 of FIG. 12 also includes example dedicated operations circuitry 1214. In this example, the dedicated operations circuitry 1214 includes special purpose circuitry 1216 that may be invoked to implement commonly used functions to avoid the need to program those functions in the field. Examples of such special purpose circuitry 1216 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 1200 may also include example general purpose programmable circuitry 1218 such as an example CPU 1220 or an example DSP 1222. Other general purpose programmable circuitry 1218 may also or alternatively be present such as a GPU, an XPU, etc., that can be programmed to perform other operations.

Although FIGS. 11 and 12 illustrate two example implementations of the programmable circuitry 1012 of FIG. 10, many other approaches are contemplated. For example, FPGA circuitry may include an on-board CPU, such as one or more of the example CPU 1220 of FIG. 11. Therefore, the programmable circuitry 1012 of FIG. 10 may also be implemented by combining at least the example microprocessor 1100 of FIG. 11 and the example FPGA circuitry 1200 of FIG. 12. In some such hybrid examples, one or more cores 1102 of FIG. 11 may execute a first portion of the machine-readable instructions represented by the flowchart(s) of FIG. 9 to perform first operation(s)/function(s), the FPGA circuitry 1200 of FIG. 12 may be at least one of configured or structured to perform second operation(s)/function(s) corresponding to a second portion of the machine-readable instructions represented by the flowchart of FIG. 9, and/or an ASIC may be at least one of configured or structured to perform third operation(s)/function(s) corresponding to a third portion of the machine-readable instructions represented by the flowcharts of FIG. 9.

Some or all of the circuitry of FIG. 2 may, thus, be instantiated at the same or different times. For example, same and/or different portion(s) of the microprocessor 1100 of FIG. 11 may be programmed to execute portion(s) of machine-readable instructions at the same and/or different times. In some examples, same and/or different portion(s) of the FPGA circuitry 1200 of FIG. 12 may be at least one of configured or structured to perform operations/functions corresponding to portion(s) of machine-readable instructions at the same and/or different times.

In some examples, some or all of the circuitry of FIG. 2 may be instantiated, for example, in one or more threads executing concurrently and/or in series. For example, the microprocessor 1100 of FIG. 11 may execute machine-readable instructions in one or more threads executing concurrently and/or in series. In some examples, the FPGA circuitry 1200 of FIG. 12 may be at least one of configured or structured to carry out operations/functions concurrently and/or in series. Moreover, in some examples, some or all of the circuitry of FIG. 2 may be implemented within one or more virtual machines or containers executing on the microprocessor 1100 of FIG. 11.

In some examples, the programmable circuitry 1012 of FIG. 10 may be in one or more packages. For example, at least one of the microprocessor 1100 of FIG. 11 or the FPGA circuitry 1200 of FIG. 12 may be in one or more packages. In some examples, an XPU may be implemented by the programmable circuitry 1012 of FIG. 10, which may be in one or more packages. For example, the XPU may include a CPU (e.g., the microprocessor 1100 of FIG. 11, the CPU 1220 of FIG. 12, etc.) in one package, a DSP (e.g., the DSP 1222 of FIG. 12) in another package, a GPU in yet another package, and an FPGA (e.g., the FPGA circuitry 1200 of FIG. 12) in still yet another package.

While an example manner of implementing the FADC 160 of FIG. 1 is illustrated in FIG. 2, one or more of the elements, processes, or devices illustrated in FIG. 2 may be combined, divided, re-arranged, omitted, eliminated, or implemented in any other way. Further, the example FADC 160 of FIG. 2, may be implemented by hardware alone or by hardware in combination with software and firmware. Thus, for example, any of the example FADC 160, could be implemented by programmable circuitry in combination with one or more machine-readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), or field programmable logic device(s) (FPLD(s)) such as FPGAs. Further still, the example FADC 160 of FIG. 2 may include one or more elements, processes, or devices in addition to, or instead of, those illustrated in FIG. 2, or may include more than one of any or all of the illustrated elements, processes and devices.

Flowchart(s) representative of example machine-readable instructions, which may be executed by programmable circuitry to at least one of implement or instantiate the FADC 160 of FIG. 2 or representative of example operations which may be performed by programmable circuitry to at least one of implement or instantiate the FADC 160 of FIG. 2, is shown in FIG. 9. The machine-readable instructions may be one or more executable programs or portion(s) of one or more executable programs for execution by programmable circuitry such as the programmable circuitry 1012 shown in the example processor platform 1000 discussed below in connection with FIG. 10 and may be one or more function(s) or portion(s) of functions to be performed by the example programmable circuitry (e.g., an FPGA) discussed below in connection with FIG. 11 or 12. In some examples, the machine-readable instructions cause an operation, a task, etc., to be carried out or performed in an automated manner in the real-world. As used herein, “automated” means without human involvement.

The program may be embodied in instructions (e.g., software and/or firmware) stored on one or more non-transitory computer readable and/or machine-readable storage medium such as one of or a combination of cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), or any other storage device or storage disk. The instructions of the non-transitory computer readable and/or machine-readable medium may program or be executed by programmable circuitry located in one or more hardware devices, but the entire program or parts thereof could alternatively be executed or instantiated by one or more hardware devices other than the programmable circuitry or embodied in dedicated hardware. The machine-readable instructions may be distributed across multiple hardware devices or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIG. 9, many other methods of implementing the example FADC 160 may alternatively be used. For example, the order of execution of the blocks of the flowchart(s) may be changed, or some of the blocks described may be changed, eliminated, or combined. Also or alternatively, any or all of the blocks of the flow chart may be implemented by one or more hardware circuits (e.g., processor circuitry, discrete, integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations or local to one or more hardware devices (e.g., a single-core processor (e.g., a single core CPU), a multi-core processor (e.g., a multi-core CPU, an XPU, etc.)). As used herein, programmable circuitry includes any type(s) of circuitry that may be programmed to perform a desired function such as, for example, one of or a combination of a CPU or an FPGA. The programmable circuitry may include one or more CPUs and/or one or more FPGAs located in the same package (e.g., the same integrated circuit (IC) package or in two or more separate housings), one or more CPUs or FPGAs in a single machine, one or multiple CPUs or FPGAs distributed across multiple servers of a server rack, multiple processors distributed across one or more server racks. Also or alternatively, programmable circuitry may include a programmable logic device (PLD), a generic array logic (GAL) device, a programmable array logic (PAL) device, a complex programmable logic device (CPLD), a simple programmable logic device (SPLD), a microcontroller (MCU), a programmable system on chip (PSoC), etc., or any combination(s) thereof in any of the contexts explained above.

The machine-readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, or produce machine executable instructions. For example, the machine-readable instructions may be fragmented and stored on one or more storage devices, disks or computing devices (e.g., servers) located at the same or different locations of a network or collection of networks (e.g., in the cloud, in edge devices, etc.). The machine-readable instructions may require one or more of installation, modification, adaptation, updating, combining, supplementing, configuring, decryption, decompression, unpacking, distribution, reassignment, compilation, etc., in order to make them directly readable, interpretable, or executable by a computing device or other machine. For example, the machine-readable instructions may be stored in multiple parts, which are individually compressed, encrypted, or stored on separate computing devices, wherein the parts when decrypted, decompressed, or combined form a set of one or more computer-executable or machine executable instructions that implement one or more functions or operations that may together form a program such as that described herein.

In another example, the machine-readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine-readable instructions may need to be configured (e.g., settings stored, data input, network addresses recorded, etc.) before the machine-readable instructions or the corresponding program(s) can be executed in whole or in part. Thus, machine-readable, computer readable or machine-readable media, as used herein, may include one or a combination of instructions and program(s) regardless of the particular format or state of the machine-readable instructions or program(s).

The machine-readable instructions described herein can be represented by any past, present, or future instruction language, scripting language, programming language, etc. For example, the machine-readable instructions may be represented using any of the following languages: C, C++, Java, C-Sharp, Perl, Python, JavaScript, HyperText Markup Language (HTML), Structured Query Language (SQL), Swift, etc.

As mentioned above, the example operations of FIG. 9 may be implemented using executable instructions (e.g., computer readable and/or machine-readable instructions) stored on one or more non-transitory computer readable or machine-readable media. As used herein, the terms non-transitory computer readable medium, non-transitory computer readable storage medium, non-transitory machine-readable medium, and non-transitory machine-readable storage medium are expressly defined to include any type of computer readable storage device or storage disk and to exclude propagating signals and to exclude transmission media. Examples of such non-transitory computer readable medium, non-transitory computer readable storage medium, non-transitory machine-readable medium, or non-transitory machine-readable storage medium include one or more optical storage devices, magnetic storage devices, an HDD, a flash memory, a read-only memory (ROM), a CD, a DVD, a cache, a RAM of any type, a register, or any other storage device or storage disk in which information is stored for any duration (e.g., for extended time periods, permanently, for brief instances, for temporarily buffering, for caching of the information). As used herein, the terms “non-transitory computer readable storage device” and “non-transitory machine-readable storage device” are defined to include any physical (mechanical, magnetic, electromechanical, or electrical) hardware to retain information for a time period, but to exclude propagating signals and to exclude transmission media. Examples of non-transitory computer readable storage devices or non-transitory machine-readable storage devices include one or a combination of random-access memory of any type, read only memory of any type, solid state memory, flash memory, optical discs, magnetic disks, disk drives, or redundant array of independent disks (RAID) systems. As used herein, the term “device” refers to physical structure such as one of or a combination of mechanical, electromechanical, or electrical equipment, hardware, or circuitry that may or may not be configured by computer readable instructions, machine-readable instructions, etc., or manufactured to execute computer-readable instructions, machine-readable instructions, etc. “Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein, “programmable circuitry” is defined to include at least one of (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., at least one of programmed or hardwired) at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and/or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means +/−10 percent of the stated value, or, if the value is zero, a reasonable range of values around zero.

Modifications are possible in the described embodiments, and other embodiments are possible, within the scope of the claims.

What is claimed is:

1. An apparatus comprising:
first voltage comparator having an input and an output;
second voltage comparator having an input and an output, the input of the second voltage comparator coupled to the input of the first voltage comparator; and
delay comparator having a first input and a second input, the first input of the delay comparator coupled to the output of the first voltage comparator, the second input of the delay comparator coupled to the output of the second voltage comparator.

2. The apparatus of claim 1, wherein the delay comparator is first delay comparator, and the apparatus further comprising:
second delay comparator having a first input and a second input; and
third delay comparator having a first input and a second input, the first input of the third delay comparator coupled to the first input of the first delay comparator and the first input of the second delay comparator, the second input of the third delay comparator coupled to the second input of the first delay comparator and the second delay comparator.

3. The apparatus of claim 1, further comprising:
first voltage-controlled delay circuitry having a first input, a second input, and an output, the first input of the first voltage-controlled delay circuitry coupled to the output of the first voltage comparator, the output of the first voltage-controlled delay circuitry coupled to the first input of the delay comparator;
second voltage-controlled delay circuitry having a first input, a second input, and an output, the first input of the second voltage-controlled delay circuitry coupled to the output of the second voltage comparator, the output of the second voltage-controlled delay circuitry coupled to the second input of the delay comparator; and
offset voltage control circuitry having a first output and a second output, the first output of the offset voltage control circuitry coupled to the second input of the first voltage-controlled delay circuitry, the second output of the offset voltage control circuitry coupled to the second input of the second voltage-controlled delay circuitry.

4. The apparatus of claim 3, wherein the first voltage-controlled delay circuitry includes:
a first transistor having a first terminal and a control terminal, the control terminal of the first transistor coupled to the first output of the offset voltage control circuitry;
a second transistor having a first terminal, a second terminal, and a control terminal, the first terminal of the second transistor coupled to the first terminal of the first transistor; and
a third transistor having a first terminal and a control terminal, the first terminal of the third transistor coupled to the first input of the delay comparator and the second terminal of the second transistor, the control terminal of the third transistor coupled to the output of the first voltage comparator and the control terminal of the second transistor.

5. The apparatus of claim 3, wherein the offset voltage control circuitry includes:
a first resistor ladder having a terminal and a plurality of outputs;
a second resistor ladder having a terminal and a plurality of outputs, the terminal of the second resistor ladder coupled to the terminal of the first resistor ladder; and
multiplexer having a plurality of inputs and an output, the plurality of inputs of the multiplexer coupled to the plurality of outputs of the first resistor ladder and the plurality of outputs of the second resistor ladder, the output of the multiplexer coupled to the second input of the first voltage-controlled delay circuitry.

6. The apparatus of claim 5, wherein the first resistor ladder includes:
a first resistor having a first terminal and a second terminal;
a second resistor having a first terminal and a second terminal, the first terminal of the second resistor coupled to the first terminal of the first resistor and a first one of the plurality of inputs of the multiplexer; and
a third resistor having a first terminal and a second terminal, the first terminal of the third resistor coupled to the second terminal of the second resistor and a second one of the plurality of inputs of the multiplexer, the second terminal of the third resistor coupled to the terminal of the second resistor ladder, the second terminal of the first resistor, and a third one of the plurality of inputs of the multiplexer.

7. The apparatus of claim 1, wherein the input of the first voltage comparator is a first input, the first voltage comparator further has a second input and a third input, the input of the second voltage comparator is a first input, the second voltage comparator further has a second input and a third input, and the apparatus further comprising voltage reference generation circuitry having a first output, a second output, a third output, and a fourth output, the first output of the voltage reference generation circuitry coupled to the second input of the first voltage comparator, the second output of the voltage reference generation circuitry coupled to the third input of the first voltage comparator, the third output of the voltage reference generation circuitry coupled to the second input of the second voltage comparator, the fourth output of the voltage reference generation circuitry coupled to the third input of the second voltage comparator.

8. The apparatus of claim 7, wherein voltage reference generation circuitry includes:
a first resistor having a terminal;
a second resistor having a first terminal and a second terminal, the first terminal of the second resistor coupled to the second input of the second voltage comparator;
a third resistor having a terminal;
a fourth resistor having a first terminal and a second terminal, the first terminal of the fourth resistor coupled to the third input of the second voltage comparator;
first offset circuitry having a first terminal and a second terminal; and
second offset circuitry having a first terminal and a second terminal, the first terminal of the second offset circuitry coupled to the terminal of the first resistor, the second terminal of the second resistor, the second input of the first voltage comparator, and the first terminal of the first offset circuitry, the second terminal of the second offset circuitry coupled to the terminal of the third resistor, the second terminal of the fourth resistor, the third input of the first voltage comparator, and the second terminal of the first offset circuitry.

9. The apparatus of claim 8, wherein the first offset circuitry includes:
first current source circuitry having a terminal;
a first switch having a first terminal and a second terminal;
a second switch having a first terminal and a second terminal, the first terminal of the second switch coupled to the terminal of the first current source circuitry and the first terminal of the first switch;
a third switch having a first terminal and a second terminal, the first terminal of the third switch coupled to the terminal of the first resistor, the second terminal of the second resistor, the second input of the first voltage comparator, and the second terminal of the first switch;
a fourth switch having a first terminal and a second terminal, the first terminal of the fourth switch coupled to the terminal of the third resistor, the second terminal of the fourth resistor, the third input of the first voltage comparator, and the second terminal of the second switch; and
second current source circuitry having a terminal coupled to the second terminal of the third switch and the second terminal of the fourth switch.

10. The apparatus of claim 1, wherein the first voltage comparator further has a sign output, the second voltage comparator further has a sign output, and the delay comparator further has a sign output, and the apparatus further comprising:
switch having a terminal;
digital-to-analog converter (DAC) circuitry having an input and an output, the input of the DAC coupled to the sign output of the first voltage comparator, the sign output of the second voltage comparator, and the sign output of the delay comparator;
a capacitor having a first terminal and a second terminal, the first terminal of the capacitor coupled to the output of the DAC; and
amplifier having an input coupled to the second input of the first voltage comparator, the second input of the second voltage comparator, the terminal of the switch, and the second terminal of the capacitor.

11. The apparatus of claim 10, wherein the amplifier further has an output, and the apparatus further comprising:
backend analog-to-digital converter (ADC) circuitry having an input and an output, the input of the backend ADC circuitry coupled to the output of the amplifier; and
alignment and correction circuitry having first inputs and second inputs, the first inputs of the alignment and correction circuitry coupled to the sign output of the first voltage comparator, the sign output of the second voltage comparator, the sign output of the delay comparator, and the input of the DAC, the second inputs of the alignment and correction circuitry coupled to the output of the backend ADC circuitry.

12. An apparatus comprising:
reference generation circuitry having a first output and a second output;
a voltage comparator stage having a first input, a second input, a first output, and a second output, the first input of the voltage comparator stage coupled to the first output of the reference generation circuitry, the second input of the voltage comparator stage coupled to the second output of the reference generation circuitry; and
a delay comparator stage having a first input and a second input, the first input of the delay comparator stage coupled to the first output of the voltage comparator stage, the second input of the delay comparator stage coupled to the second output of the voltage comparator stage.

13. The apparatus of claim 12, wherein the voltage comparator stage includes:
first voltage comparator having a first input, a second input, and an output, the first input of the first voltage comparator coupled to the first output of the reference generation circuitry, the output of the first voltage comparator coupled to the first input of the delay comparator stage; and
second voltage comparator having a first input, a second input, and an output, the first input of the second voltage comparator coupled to the second output of the reference generation circuitry, the second input of the second voltage comparator coupled to the second input of the first voltage comparator, the output of the second voltage comparator coupled to the second input of the delay comparator stage.

14. The apparatus of claim 12, wherein the delay comparator stage includes:
first voltage-controlled delay circuitry having an input and an output, the input of the first voltage-controlled delay circuitry coupled to the first output of the voltage comparator stage;
second voltage-controlled delay circuitry having an input and an output, the input of the second voltage-controlled delay circuitry coupled to the second output of the voltage comparator stage; and
delay comparator having a first input and a second input, the first input of the delay comparator coupled to the output of the first voltage-controlled delay circuitry, the second input of the delay comparator coupled to the output of the second voltage-controlled delay circuitry.

15. The apparatus of claim 14, wherein the delay comparator is first delay comparator, and the delay comparator stage further includes:
third voltage-controlled delay circuitry having an input and an output, the input of the third voltage-controlled delay circuitry coupled to the first output of the voltage comparator stage and the input of the first voltage-controlled delay circuitry;
fourth voltage-controlled delay circuitry having an input and an output, the input of the fourth voltage-controlled delay circuitry coupled to the second output of the voltage comparator stage and the input of the second voltage-controlled delay circuitry; and
second delay comparator having a first input and a second input, the first input of the second delay comparator coupled to the output of the third voltage-controlled delay circuitry, the second input of the second delay comparator coupled to the output of the fourth voltage-controlled delay circuitry.

16. The apparatus of claim 12, wherein the voltage comparator stage further has sign outputs, the delay comparator stage further has sign outputs, and the apparatus further comprising:
an digital-to-analog converter (DAC) having inputs; and
alignment and correction circuitry having an inputs coupled to the sign outputs of the voltage comparator stage, the sign outputs of the delay comparator stage, and the inputs of the DAC, the alignment and correction circuitry configured to generate a digital value responsive to the sign outputs of the voltage comparator stage and the sign outputs of the delay comparator stage.

17. An apparatus comprising:
analog-to-digital converter (ADC) circuitry including:
a voltage comparator stage having an input, a sign output, a first delay output, and a second delay output; and
a delay comparator stage having a first input, a second input, and a sign output, the first input of the delay comparator stage coupled to the first delay output of the voltage comparator stage, the second input of the delay comparator stage coupled to the second delay output of the voltage comparator stage;
a digital-to-analog converter (DAC) having an input and an output, the input of the DAC coupled to the sign output of the voltage comparator stage and the sign output of the delay comparator stage; and
amplifier having an input coupled to the input of the voltage comparator stage and the output of the DAC.

18. The apparatus of claim 17, wherein the input of the voltage comparator stage is a first input, the voltage comparator stage further has a second input and a third input, the delay comparator stage further has a third input and a fourth input, and the apparatus further comprising:
reference generation circuitry having a first output and a second output, the first output of the reference generation circuitry coupled to the second input of the voltage comparator stage, the second output of the reference generation circuitry coupled to the third input of the voltage comparator stage; and
offset voltage control circuitry having a first output and a second output, the first output of the offset voltage control circuitry coupled to the third input of the delay comparator stage, the second output of the offset voltage control circuitry coupled to the fourth input of the delay comparator stage.

19. The apparatus of claim 17, wherein the voltage comparator stage includes:
first voltage comparator having an input, a sign output, and a delay output, the sign output of the first voltage comparator coupled to the input of the DAC, the delay output of the first voltage comparator coupled to the first input of the delay comparator stage; and
second voltage comparator having an input, a sign output, and a delay output, the input of the second voltage comparator coupled to the output of the DAC, the input of the amplifier, and the input of the first voltage comparator, the sign output of the second voltage comparator coupled to the input of the DAC, the delay output of the second voltage comparator coupled to the second input of the delay comparator stage.

20. The apparatus of claim 17, wherein the delay comparator stage includes:
first voltage-controlled delay circuitry having an input and an output, the input of the first voltage-controlled delay circuitry coupled to the first delay output of the voltage comparator stage;
second voltage-controlled delay circuitry having an input and an output, the input of the second voltage-controlled delay circuitry coupled to the second delay output of the voltage comparator stage; and
delay comparator having a first input, a second input, and a sign output, the first input of the delay comparator coupled to the output of the first voltage-controlled delay circuitry, the second input of the delay comparator coupled to the output of the second voltage-controlled delay circuitry, the sign output of the delay comparator coupled to the input of the DAC.
